(19) United States
(12) Patent Application Publication
(10) Pub. No.: US 2009/0311621 A1
(43) Pub. Date: Dec. 17, 2009

(54) SUPPORT FOR PLANOGRAPHIC PRINTING PLATE MATERIAL, MANUFACTURING METHOD THEREOF, AND PLANOGRAPHIC PRINTING PLATE MATERIAL EMPLOYING THE SAME

(75) Inventor: Hiroshi Takagi, Tokyo (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA MEDICAL & GRAPHIC, INC., Tokyo (JP)

(21) Appl. No.: 12/158,017

(22) PCT Filed: Nov. 9, 2006
(86) PCT No.: PCT/JP2006/322359

§ 371 Date: Jun. 18, 2008

(30) Foreign Application Priority Data
Dec. 22, 2005 (JP) 2005369322

(51) Int. Cl. G03F 7/004; C25D 5/34; B32B 3/00; B41N 1/08; B41N 3/03

(52) U.S. Cl. 430/270.1; 205/205; 428/142; 503/200

(57) ABSTRACT

An objective is to provide a light sensitive planographic printing plate material exhibiting excellent tone reproduction, printing durability and anti-stain property during printing at high printing pressure; a support employed for the material; a manufacturing method thereof; and a plate-making method of the light sensitive planographic printing plate material. Also disclosed is a method of manufacturing a support for a planographic printing plate material, possessing the steps of conducting specific treatments on an aluminum plate as the support in that order, wherein the aluminum plate in each of the following methods comprises a Mg content of 0.1-0.4% by weight, a Ga content of 0.001-0.02% by weight, and an Al content of at least 99.0% by weight.

### TECHNICAL FIELD

The present invention relates to a support for a planographic printing plate material, a manufacturing thereof and the planographic printing plate material employing the same, and specifically to a light sensitive planographic printing plate utilized for a so-called computer-to-plate (hereinafter, referred to as CTP) system.

### BACKGROUND

In recent years, a digital technique by image information is electronically processed, stored and output employing a computer has widely become popular, and a so-called CTP system in which highly directional laser light is scanned in accordance with the digitalized image information to conduct recording directly onto a light sensitive planographic printing plate is developed as a production technology of an offset printing plate, and has been put to practical use.

It is commonly known that among these, a printing plate material comprising an aluminum support and provided thereon, an image recording layer is used in the printing field in which a relatively high printing durability is required.

As the aluminum support, an aluminum plate subjected to surface-roughening treatment and anodizing treatment is generally used, however, when a large quantity of copies are printed employing a printing plate having such an aluminum plate, there are problems that a small dot image may be damaged or stain may occur at non-image portions. Further, there is a problem such that tone reproduction, printing durability and an anti-stain property are degraded during printing at high printing pressure, since printing is often conducted specifically for a packaging material by increasing higher printing pressure than usual in order to increase the concentration of ink at image portions.

As a printing plate material to solve the above problems, a printing plate material is proposed in for example, Japanese Patent O.P.I Publication No. 2000-255177, which comprises a grained aluminum support, having protrusions with a specific average height consisting of boehmite on the surface, and provided thereon, a polymerizable light sensitive layer.

Known is a printing plate material comprising an aluminum support which is subjected to a specific surface-roughening treatment, anodizing treatment, and then hydrophilization treatment employing polyvinyl phosphonic acid (refer to Patent Document 1, for example), or a printing plate material comprising an aluminum support and a light sensitive layer, an intermediate layer containing polyvinyl phosphonic acid between the aluminum support and the light sensitive layer (refer to Patent Document 2, for example).

However, when a lot of printing is conducted for the above-described printing plate material, small dot damage and a stain during printing tend to be generated, and tone reproduction, printing durability and an anti-stain property have been insufficient specifically during printing at high printing pressure.

The printing, in which VOC-free printing ink (“VOC” means volatile organic compounds) and recycled paper are employed for recent environmental consciousness, has been particularly insufficient in view of the foregoing.

Patent Document 1: Japanese Patent O.P.I. Publication No. 2002-103834

Patent Document 2: Japanese Patent Examined Publication No. 2003-57831

### DISCLOSURE OF THE INVENTION

### Problems to be Solved by the Invention

The present invention was made on the basis of the above-described situation. It is an object of the present invention to provide a light sensitive planographic printing plate material exhibiting excellent tone reproduction, printing durability and anti-stain property during printing at high printing pressure; a support employed for the material; a manufacturing method thereof, and a plate-making method of the light sensitive planographic printing plate material.

### Means to Solve the Problems

The object of the present invention is accomplished by the following structures.

(Structure 1) A method of manufacturing a support for a planographic printing plate material, comprising the steps of (1) conducting an alkali etching treatment on an aluminum plate as the support; (2) electrochemically conducting a surface-roughening treatment in a nitric acid solution as well as in a hydrochloric acid solution in arbitrary order; and (3) conducting an anodizing treatment, in this order, wherein the aluminum plate comprises a Mg content of 0.1-0.4% by weight, a Ga content of 0.001-0.02% by weight, and an Al content of at least 99.0% by weight.

(Structure 2) A method of manufacturing a support for a planographic printing plate material, comprising the steps of (1) conducting an alkali etching treatment on an aluminum plate as the support; (2) electrochemically conducting a surface-roughening treatment in a nitric acid solution; (3) electrochemically conducting a surface-roughening treatment in a hydrochloric acid solution; and (4) conducting an anodizing treatment, in this order, wherein the aluminum plate comprises a Mg content of 0.1-0.4% by weight, a Ga content of 0.001-0.02% by weight, and an Al content of at least 99.0% by weight.

(Structure 3) A method of manufacturing a support for a planographic printing plate material, comprising the steps of (1) conducting an alkali etching treatment on an aluminum plate as the support; (2) electrochemically conducting a surface-roughening treatment in a nitric acid solution; (3) conducting the alkali etching treatment; (4) electrochemically conducting a surface-roughening treatment in a hydrochloric acid solution; (5) conducting the alkali etching treatment; and (6) conducting an anodizing treatment, in this order, wherein the aluminum plate comprises a Mg content of 0.1-0.4% by weight, a Ca content of 0.001-0.02% by weight, and an Al content of at least 99.0% by weight.

(Structure 4) A method of manufacturing a support for a planographic printing plate material, comprising the steps of (1) conducting an alkali etching treatment on an aluminum plate as the support; (2) electrochemically conducting a surface-roughening treatment in a nitric acid solution; (3) conducting a phosphoric acid-desmutting treatment; (4) electrochemically conducting a surface-roughening treatment in a hydrochloric acid solution; (5) conducting the phosphoric acid-desmutting treatment; and (6) conducting an anodizing treatment, in this orders wherein the aluminum plate comprises a Mg content of 0.1-0.4% by weight, a Ca content of 0.001-0.02% by weight, and an Al content of at least 99.0% by weight.

(Structure 5) The support manufactured by the method of any one of Structures 1-4.

(Structure 6) A planographic printing plate material comprising the support of Structure 5 and provided thereon, an image formation layer.

(Structure 7) The planographic printing plate material of Structure 6, wherein the image formation layer is a thermosensitive image formation layer.

(Structure 8) The planographic printing plate material of Structure 6 or 7, wherein the image formation layer is a photopolymerizable image formation layer.

(Structure 9) The planographic printing plate material of any one of Structures 6-8, wherein the image formation layer is an on-press developable layer.

### EFFECT OF THE INVENTION

The structures of the present invention are possible to provide a light sensitive planographic printing plate material exhibiting excellent tone reproduction, printing durability and anti-stain property during printing at high printing pressure; a support employed for the material; a manufacturing method thereof; and a plate-making method of the light sensitive planographic printing plate material.

### DESCRIPTION OF THE PREFERRED EMBODIMENTS

Next, the present invention will be described in detail.

### (Support for Planographic Printing Plate Material)

The present invention has a feature in a method of manufacturing a support for a planographic printing plate material, comprising the steps of conducting the following treatments in that order, wherein the aluminum plate in each of the following methods comprises a Mg content of 0.1-0.4% by weight, a Ga content of 0.001-0.02% by weight, and an Al content of at least 99.0% by weight.

Method 1 comprising the steps of (1) conducting an alkali etching treatment on an aluminum plate as the support; (2) electrochemically conducting a surface-roughening treatment in a nitric acid solution as well as in a hydrochloric acid solution in arbitrary order; and (3) conducting an anodizing treatment.

Method 2 comprising the steps of (1) conducting an alkali etching treatment on an aluminum plate as the support; (2) electrochemically conducting a surface-roughening treatment in a nitric acid solution; (3) electrochemically conducting a surface-roughening treatment in a hydrochloric acid solution; and (4) conducting an anodizing treatment.

Method 3 comprising the steps of (1) conducting an alkali etching treatment on an aluminum plate as the support; (2) electrochemically conducting a surface-roughening treatment in a nitric acid solution; (3) conducting the alkali etching treatment; (4) electrochemically conducting a surface-roughening treatment in a hydrochloric acid solution; (5) conducting the alkali etching treatment; and (6) conducting an anodizing treatment.

Method 4 comprising the steps of (1) conducting an alkali etching treatment on an aluminum plate as the support; (2) electrochemically conducting a surface-roughening treatment in a nitric acid solution; (3) conducting a phosphoric acid-desmutting treatment; (4) electrochemically conducting a surface-roughening treatment in a hydrochloric acid solution; (5) conducting the phosphoric acid-desmutting treatment; and (6) conducting an anodizing treatment.

In the present invention, an aluminum plate is employed as a support for a planographic printing plate material, and as the aluminum plate, any of a pure aluminum plate and an aluminum alloy plate is usable.

Various alloys are usable as the aluminum alloy. Examples thereof include alloys of aluminum and a metal such as silicon, copper, manganese, magnesium, chromium, zinc, lead, bismuth, nickel, titanium, sodium or iron, and aluminum plates prepared by various rolling methods are usable.

A recycled aluminum plate obtained by rolling aluminum recycled from scrapped or recycled materials, which has recently spread, can be also used.

The present invention has a feature including a Mg content of 0.1-0.4% by weight, a Ca content of 0.001-0.02% by weight, and an Al content of at least 99.0% by weight.

In the case of a Mg content of less than 0.1% by weight, an evenly and finely roughened surface is difficult to be obtained via the after-mentioned electrolytic surface-roughening treatment, and further, in the case of a Mg content exceeding 0.4% by weight, coarse pits tend to be easily formed, whereby no effect of the present invention can be produced.

In the case of a Ga content of less than 0.001% by weight, an evenly and finely roughened surface is difficult to be obtained via the electrolytic surface-roughening treatment, and further, in the case of a Ga content exceeding 0.02% by weight, coarse pits tend to be easily formed, whereby no effect of the present invention can be produced.

An aluminum plate, on which a roughened surface is formed by transferring a roughened surface in advance, may be employed as an aluminum plate of the present invention, and a roughened surface may also be formed by transferring a roughened pattern onto an aluminum plate. A process of forming a roughened surface via rolling is not limited, but a rolling process is preferably conducted employing a rolling mill roll. A roughened surface can be formed via lamination-rolling, transfer and so forth in the final rolling process to use an aluminum plate.

### <Surface-Roughening>

Subsequently, a surface-roughening treatment is carried out. In the present invention, after transferring a roughened surface pattern onto the aluminum plate surface, an alkali etching treatment is conducted, and subsequently, a surface-roughening treatment is electrochemically conducted in a nitric acid and/or in a hydrochloric acid, if desired, but a mechanical surface-roughening treatment may also be carried out before that.

Though there is no restriction for the mechanical surface-roughening treatment, a brushing roughening method and a honing roughening method are preferable. The brushing roughening method is carried out by rubbing the surface of the plate with a rotating brush with a brush hair with a diameter of 0.2-0.8 mm, while supplying slurry in which volcanic ash particles with a particle diameter of 10-100 μm are dispersed in water to the surface of the plate. The honing roughening method is carried out by ejecting obliquely slurry with pressure applied from nozzles to the surface of the plate, the slurry containing volcanic ash particles with a particle diameter of 10-100 μm dispersed in water. Surface-roughening can also be carried out by laminating the plate surface with a sheet on the surface of which abrading particles with a particle diameter of 10-100 μm has been coated at intervals of 100-200 μm and at a density of 2.5×10³-10×10³/cm², and then applying pressure to the laminated sheet to transfer the roughened pattern of the sheet, whereby the plate surface is roughened.

In the present invention, after mechanically conducting a surface-roughening treatment by a mechanical surface-roughening method, an alkali etching treatment is carried out before electrochemically conducting a surface-roughening treatment. The alkali etching treatment means a treatment in which a surface layer is dissolved by bringing the above-described aluminum plate into contact with an alkali solution.

The alkali etching treatment carried out before electrochemically conducting a surface-roughening treatment is conducted for the purpose of forming even concave portions via the electrochemical surface-roughening treatment, and of removing rolling oil on the surface of an aluminum plate (rolled aluminum), contamination, a natural oxidation film, aluminum dust generated via a mechanical surface-roughening treatment, and abrasives.

As to the alkali etching treatment, an etching amount of at least 0.1 g/m² is preferable, an etching amount of at least 0.5 g/m² is more preferable, and an etching amount of at least 1 g/m² is further preferable. In addition, an etching amount of not more than 10 g/m² is preferable, an etching amount of not more than 8 g/m² is more preferable, an etching amount of not more than 5 g/m² is still more preferable, and an etching amount of not more than 3 g/m² is further preferable. In the case of a very small etching amount, no even pit formation can be generated via an electrochemical surface-roughening treatment, whereby the unevenness tends to be generated. On the other hand, in the case of a very large etching amount, a large consumption amount of an aqueous alkali solution causes an economical disadvantage.

As alkali employed for an alkali solution, for example, caustic alkali and an alkali metal salt are provided. Specific examples of the caustic alkali include caustic sodium and caustic potassium. Further, examples of the alkali metal salt include alkali metal silicate such as sodium metasilicate, sodium silicate, potassium metasilicate, potassium silicate or the like; alkali metal carbonate such as such as sodium carbonate, potassium carbonate or the like; alkali metal aluminate such as sodium aluminate, potassium aluminate or the like; alkali metal aldonate such as sodium gluconate, potassium gluconate or the like; alkali metal hydrogenphosphate such as disodium phosphate, dipotassium phosphate, trisodium phosphate, tripotassium phosphate or the like. Of these, a caustic alkali solution and a solution containing both caustic alkali and alkali metal aluminate are preferable in view of a high speed of etching and low cost. An aqueous caustic sodium solution is specifically preferable.

As to the alkali etching treatment, an alkali solution concentration of at least 30 g/l is preferable, and an alkali solution concentration of at least 300 g/l is more preferable. In addition, an alkali solution concentration of not more than 500 g/l is preferable, and an alkali solution concentration of not more than 450 g/l is more preferable.

Further, the alkali solution preferably contains an aluminum ion. An aluminum ion concentration of at least 1 g/l is preferable, and an aluminum ion concentration of at least 50 g/l is more preferable in addition, an aluminum ion concentration of not more than 200 g/l is preferable, and an aluminum ion concentration of not more than 150 g/l is more preferable. Such the alkali solution can be prepared employing water, and 48% by weight of an aqueous caustic sodium solution and an aqueous sodium aluminate solution.

As to the alkali etching treatment, an alkali solution preferably has a temperature of at least 30° C., and an alkali solution more preferably has a temperature of at least 50° C. In addition, an alkali solution preferably has a temperature of not more than 80° C., and an alkali solution more preferably has a temperature of not more than 75° C.

As to the alkali etching treatment, a treatment time of at least 1 second is preferable, and a treatment time of at least 2 seconds is more preferable. In addition, a treatment time of not more than 30 seconds is preferable, and a treatment time of not more than 15 seconds is more preferable.

Examples of a method of bringing an aluminum plate into contact with an alkali solution include a method by which an aluminum plate passes through the inside of a tank in which an alkali solution is charged, a method by which an aluminum plate is immersed in a tank in which an alkali solution is charged, and a method by which an alkali solution is sprayed onto the aluminum plate surface.

After completing an alkali etching treatment, liquid is drained by a nip roller, and after further conducting a washing treatment for 1-10 seconds, it is preferable that liquid is drained by a nip roller.

After conducting an alkali etching treatment on an aluminum plate as the support, an aluminum plate is preferably immersed in an acid such as a phosphoric acid, a nitric acid, a sulfuric acid, chromic acid or the like, or a mixed acid thereof to conduct a neutralization treatment.

In the electrolytic surface-roughening treatment carried out in the electrolytic solution containing a nitric acid as a main component, applied voltage is generally selected to be 1-50 V, but preferably selected to be 10-30 V. The utilized current density can be selected from the range of 10-200 A/dm², and is preferably 20-100 A/dm². The quantity of electricity can be selected from the range of 100-5000 C/dm², and is preferably 100-2000 C/dm². The temperature during the electrolytic surface-roughening treatment may be in the range of 10-50° C., and is preferably 15-45° C. The nitric acid concentration in the electrolytic solution is preferably 0.1-5% by weight. It is possible to optionally add, to the electrolytic solution, nitrates, chlorides, amines, aldehydes, phosphoric acid, chromic acid, boric acid, acetic acid, oxalic acid or aluminum ion.

In the electrolytic surface-roughening treatment carried out in the electrolytic solution containing a hydrochloric acid as a main component, applied voltage is generally selected to be 1-50 V, but preferably selected to be 10-30 V. The hydrochloric acid concentration is 5-20 g/l, and preferably 6.5-16 g/l. Temperature of the electrolytic solution is 15-35° C., and preferably 18-38° C. The aluminum ion concentration in an electrolytic solution is 0.5-15 g/l, and preferably 0.7-10 g/l. An acetic acid or a boric acid is preferably contained in an electrolytic solution, and the concentration is 1-20 g/l, and preferably 3-15 g/l. The ratio with respect to the hydrochloric acid concentration is preferably 0.5-1.5. The current density is 15-120 A/dm², and preferably 20-90 A/dm². The quantity of electricity is 400-2000 C/dm², and preferably 500-1200 C/dm². A frequency of 40-150 Hz is preferably employed.

As an embodiment of the present invention, after conducting an electrolytic surface-roughening treatment, an alkali etching treatment is carried out in order to remove smut (contamination remaining on the surface) produced via an electrolytic surface-roughening treatment. An alkali etching treatment in each of the steps can be carried out similarly to the above-described.

After conducting the alkali etching treatment, further, acid washing (desmutting treatment) is preferably carried out in order to remove the smut. The desmutting treatment is conducted by bringing an aluminum plate into contact with an acidic solution. That is, it is preferable for the plate to be dipped in an acid such as a phosphoric acid, a nitric acid, a sulfuric acid or a chromic acid, or in a mixed acid thereof, for neutralization.

As an embodiment of the present invention, after conducting an electrolytic surface-roughening treatment, a process is conducted in an acidic solution containing a phosphoric acid as a main component in order to remove smut produced via an electrolytic surface-roughening treatment. The phosphoric acid concentration is 25-450 g/l, and preferably 75-250 g/l.

The acidic solution containing a phosphoric acid as a main component preferably contains an aluminum ion. An aluminum ion concentration of 0.01-10 g/l is preferable, and an aluminum ion concentration of 1-5 g/l is more preferable.

The acidic solution preferably has a liquid temperature of 30-80° C., and more preferably has a liquid temperature of 35-75° C.

An anodidation treatment is carried out after electrochemically conducting a surface-roughening treatment.

The method of conducting an anodizing treatment is not specifically limited, and commonly known methods can be used. The anodizing treatment forms an anodization film on the plate surface. Generally, the anodizing treatment is carried out in an electrolytic solution containing a sulfuric acid, a phosphoric acid or their mixture applying a direct current.

In the present invention, the anodizing treatment is preferably carried out in a sulfuric acid solution as an electrolytic solution. A sulfuric acid concentration of 5-50% by weight is preferable, and a sulfuric acid concentration of 10-35% by weight is more preferable. The sulfuric acid solution preferably has a temperature of 10-50° C. An applied voltage of at least 18 V is preferable, and an applied voltage of at least 20 V is more preferable. A current density of 1-30 A/dm² is preferable. The quantity of electricity is preferably 20-500 C/dm².

The coated amount of the formed anodization film is preferably 1.0-10.0 mg/dm², and more preferably 2.0-8.0 mg/dm².

The coated amount of the formed anodization film can be obtained from the difference between weights of the aluminum plates before and after the formed anodization film is dissolved in for example, an aqueous phosphoric acid chromic acid solution which is prepared by dissolving 35 ml of a 85% by weight phosphoric acid solution and 20 g of chromium (IV) oxide in 1 liter of water. Micropores are formed in the anodization film. The micropore density in the anodization film is preferably 400-700/μm², and more preferably 400-600/μm².

The aluminum plate, which has been subjected to anodizing treatment, is optionally subjected to a sealing treatment. For the sealing treatment, it is possible to use known methods using hot water, boiling water, steam, a sodium silicate solution, an aqueous dichromate solution, a nitrite solution and an ammonium acetate solution.

In the present invention, the aluminum plate obtained after conducting these treatment steps is preferably subjected to a hydrophilization treatment, if desired. The method of conducting a hydrophilization treatment is not specifically limited, but there is a method of coating on the plate water soluble resins such as polyvinyl phosphonic acid, a homopolymer or copolymer having in the side chain a sulfonic acid group, polyacrylic acid, water soluble metal salts (for example, zinc borate), yellow dyes or amine salts Sol-gel treatment substrate as disclosed in Japanese Patent O.P.I. Publication No. 5-304358 is used which forms a covalent bond with a functional group capable of causing addition reaction by radicals. The hydrophilization treatment is preferably carried out on the support surface employing polyvinyl phosphonic acid. As the treating methods, there are, for example, a coating method, a spraying method, or a dipping method, and the present invention is not limited thereto. The dipping method is preferred in that the facility is cheap. An aqueous polyvinyl phosphonic acid solution used in the dipping method is preferably an aqueous 0.05-3% polyvinyl phosphonic acid solution. The treatment temperature is preferably 20-90° C., and the treatment time is preferably 10-180 seconds. After conducting the hydrophilization treatment, excessive polyvinyl phosphonic acid is preferably removed from the aluminum plate surface through washing or squeegeeing. After that, the resulting aluminum plate is preferably dried, and the drying temperature is preferably 20-95° C.

In addition, as a more preferred embodiment of the present invention, there is one in which an electrochemical surface-roughening treatment is conducted in a nitric acid solution as well as in a hydrochloric acid solution in this order, but in order to produce effects of the objective, it is preferable that an electrochemical surface-roughening treatment is also conducted in a nitric acid solution as well as in a hydrochloric acid solution in arbitrary order.

Further, in a treatment embodiment after conducting the electrochemical surface-roughening treatment, an alkali etching treatment is further preferably effective in view of dot reproduction and an anti-stain property, a phosphoric acid-desmutting treatment is further preferably effective in view of printing durability.

### (Image Formation Layer)

The light sensitive planographic printing plate material of the present invention has an image formation layer on the roughened surface side of the support for the above-described planographic printing plate material.

The image formation layer in the present invention is a layer capable of forming an image via imagewise exposure. As the image formation layer, a positive or negative working image formation layer used in a conventional planographic printing plate material can be used.

As the image formation layer in the present invention, a thermosensitive image formation layer or a polymerizable image formation layer is preferably used.

As the thermosensitive image formation layer, a layer capable of forming an image employing heat generated via laser exposure is preferably utilized.

As the layer capable of forming an image employing heat generated via laser exposure, a positive working thermosensitive image formation layer containing a compound capable of being decomposed by an acid or a negative working image formation layer such as a thermosensitive image formation layer containing a polymerizable composition or a thermosensitive image formation layer containing a thermoplastic material are preferably used.

Removal of the thermosensitive image formation layer is preferably carried out on a printing press. That is, the thermosensitive image formation layer is preferably an on-press developable layer.

The on-press developable layer refers to one in which after imagewise exposed, the non-image portions are removable by supplying dampening water and/or printing ink during planographic printing.

As the positive working image formation layer containing a compound capable of being decomposed by an acid, there is, for example, an image formation layer containing a photo-acid generating agent capable of generating an acid on laser exposure, an acid decomposable compound, which is decomposed by the generated acid to increase solubility to a developer, and an infrared absorber, as disclosed in Japanese Patent O.P.I. Publication No. 9-171254.

As the photo-acid generating agents, there are various conventional compounds and mixtures. For example, a salt of diazonium, phosphonium, sulfonium or iodonium ion with BF₄⁻, PF₆⁻, SbF₆⁻ SiF₆²⁻ or ClO₄⁻, an organic halogen-containing compound, o-quinone-diazidesulfonylchloride or a mixture of an organic metal and an organic halogen-containing compound is an actinic light sensitive component capable of generating or releasing an acid upon exposure to actinic light, and can be used as the photo-acid generating agent in the present invention. In principle, the organic halogen-containing compound, which is known as a photoinitiator capable of forming a free radical, is a compound capable of generating a hydrogen halide and can be used as the photo-acid generating agent. The examples of the organic halogen-containing compound capable of forming a hydrogen halide include those disclosed in U.S. Pat. Nos. 3,515,552, 3,536,489 and 3,779,778 and West German Patent No. 2,243,621, and compounds generating an acid by photodegradation disclosed in West German Patent No. 2,610,842. As the photo-acid generating agent, o-naphthoquinone diazide-4-sulfonylhalogenides disclosed in Japanese Patent O.P.I. Publication No. 50-36209 can be also used.

As the photo-acid generating agent, an organic halogen-containing compound is preferred in view of sensitivity to infrared rays and storage stability. The organic halogen-containing compounds are preferably halogenated alkyl-containing triazines or halogenated alkyl-containing oxadiazoles, and especially preferably halogenated alkyl-containing s-triazines.

The content of the photo-acid generating agent in the light sensitive layer is preferably 0.1-20% by weight, and more preferably 0.2-10% by weight based on the total weight of the solid content of the image formation layer, although the content broadly varies depending on its chemical properties, or kinds or physical properties of image formation layer used.

As the acid decomposable compounds, there are compounds having a C—O—C bond disclosed in Japanese Patent O.P.I. Publication Nos. 48-89003, 51-120714, 53-133429, 55-12995, 55-126236 and 56-17345, compounds having an Si—O—C bond disclosed in Japanese Patent O.P.I. Publication Nos. 60-37549 and 60-121446, another acid decomposable compound disclosed in Japanese Patent O.P.I. Publication Nos. 60-3625 and 60-10247, compounds having an Si—N bond disclosed in Japanese Patent O.P.I. Publication No. 61-16687, carbonic acid esters disclosed in Japanese Patent O.P.I. Publication No. 61-94603, orthocarbonic acid esters disclosed in Japanese Patent O.P.I. Publication No. 60-251744, orthotitanic acid esters disclosed in Japanese Patent O.P.I. Publication No. 61-125473, orthosilicic acid esters disclosed in Japanese Patent O.P.I. Publication No. 61-125474, acetals or ketals disclosed in Japanese Patent O.P.I. Publication No. 61-155481, and compounds having a C—S bond disclosed in Japanese Patent O.P.I. Publication No. 61-87769. Of these compounds, the compounds having a C—O—C bond, the compounds having an Si—O—C bond, orthocarbonic acid esters, the acetals or ketals as described above and silyl ethers disclosed in Japanese Patent O.P.I. Publication Nos. 53-133429, 56-17345, 60-121446, 60-37549, 60-251744 and 61-155481 described previously are preferred.

The content of the acid decomposable compound in the light sensitive layer is preferably 5-70% by weight, and more preferably 10-50% by weight based on the total weight of the solid content of the image formation layer. The acid decomposable compounds may be used singly or as an admixture of at least two kinds thereof.

This thermosensitive image formation layer preferably contains a light-to-heat conversion agent capable of converting exposure light to heat. The following light-to-heat conversion dyes and other light-to-heat conversion agents are used as the light-to-heat conversion material.

### [Light-to-Heat Conversion Dye]

The following light-to-heat conversion dyes can be utilized.

Examples of conventional infrared absorbing dyes include a cyanine dye, a chloconium dye, a polymethine dye, an azulenium dye, a squalenium dye, a thiopyrylium dye, a naphthoquinone dye or an anthraquinone dye, and an organometallic complex such as a phthalocyanine compound, a naphthalocyanine compound, an azo compound, a thioamide compound, a dithiol compound or an indoaniline compound. Exemplarily, the light-to-heat conversion agents include those disclosed in Japanese Patent O.P.I. Publication Nos. 63-139191, 64-33547, 1-160683, 1-280750, 1-293342, 2-2074, 3-26593, 3-30991, 3-34891, 3-36093, 3-36094, 3-36095, 3-42281, 3-97589 and 3-103476. These compounds may be used singly or in combination.

Those described in Japanese Patent O.P.I Publication Nos. 11-240270, 11-265062, 2000-309174, 2002-49147, 2001-162965, 2002-144750, and 2001-219667 can be preferably used.

### [Light-to-Heat Conversion Agents]

In addition to the above-described light-to-heat conversion dyes, other light-to-heat conversion agents can be used in combination.

Preferred examples of the light-to-heat conversion agents include carbon, graphite, metal and metal oxide.

Furnace black and acetylene black is preferably used as the carbon. The graininess (d₅₀) thereof is preferably not more than 100 nm, and more preferably not more than 50 nm.

The graphite is one having a particle size of preferably not more than 0.5 μm, more preferably not more than 100 nm, and most preferably not more than 50 nm.

As the metal, any metal can be used as long as the metal is in a form of fine particles having preferably a particle size of not more than 0.5 μm, more preferably not more than 100 nm, and most preferably not more than 50 nm. The metal may have any shape such as spherical, flaky and needle-like. Colloidal metal particles such as those of silver or gold are particularly preferred.

As the metal oxide, materials having black color in the visible regions or materials which are conductive or semi-conductive can be used.

Examples of the former include black iron oxide (Fe₃O₄) and black complex metal oxides containing at least two metals.

Examples of the latter include Sb-doped SnO₂ (ATO), Sn-added In₂O₃ (TTO), TiO₂, TiO prepared by reducing TiO₂ (titanium oxide nitride, generally titanium black).

Particles prepared by covering a core material such as BaSO₄, TiO₂, 9Al₂O₃.2B₂O and K₂O.nTiO₂ with these metal oxides is usable.

These oxides are particles having a particle size of not more than 0.5 μm, preferably not more than 100 nm, and more preferably not more than 50 nm.

As these light-to-heat conversion agents, black iron oxide or black complex metal oxides containing at least two metals are more preferred.

Examples of the black complex metal oxides include complex metal oxides comprising at least two selected from Al, Ti, Cr, Mn, Fe, Co, Ni, Cu, Zn, Sb, and Ba. These can be prepared according to the methods disclosed in Japanese Patent O.P.I. Publication Nos. 8-27393, 9-25126, 9-237570, 9-241529 and 10-231441.

The complex metal oxide used in the present invention is preferably a complex Cu—Cr—Mn system metal oxide or a Cu—Fe—Mn system metal oxide. The Cu—Cr—Mn system metal oxides are preferably subjected to the treatment disclosed in Japanese Patent O.P.I. Publication Nos. 8-27393 in order to reduce isolation of a 6-valent chromium ion. These complex metal oxides have a high color density and a high light-to-heat conversion efficiency as compared with another metal oxide.

The average primary particle diameter of these complex metal oxides is preferably not more than 1.0 μm, and more preferably 0.01-0.5 μm. The average primary particle diameter of not more than 1.0 μm improves light-to-heat conversion efficiency relative to the addition amount of the particles, and the average primary particle diameter of 0.01-0.5 μm further improves light-to-heat conversion efficiency relative to the addition amount of the particles.

The light-to-heat conversion efficiency relative to the addition amount of the particles depends on a particle dispersity, and the well-dispersed particles have high light-to-heat conversion efficiency.

Accordingly, these complex metal oxide particles are preferably dispersed according to a known dispersing method, separately to a dispersion liquid (paste), before being added to a coating liquid for the particle containing layer. The metal oxides having an average primary particle diameter of less than 0.01 are not preferred since they are difficult to be dispersed. A dispersant is optionally used for dispersion. The addition amount of the dispersant is preferably 0.01-5% by weight, and more preferably 0.1-2% by weight, based on the weight of the complex metal oxide particles.

The image formation layer optionally contains a binder.

As a positive working image formation layer, an image formation layer containing o-naphthoquinone is preferably used.

The light-to-heat conversion material described above may be contained in the image formation layer or in a layer adjacent thereto.

As the thermosensitive image formation layer containing a polymerizable composition described above, there is a thermosensitive image formation layer containing (a) a light-to-heat conversion agent having an absorption band in a wavelength region of 700-1300 nm, (b) a polymerization initiator and (c) a polymerizable unsaturated compound.

{(a) Light-to-Heat Conversion Agent Having an Absorption Band in a Wavelength Region of 700-1300 nm}

As the light-to-heat conversion agent having an absorption band in a wavelength region of 700-1300 nm, There are the infrared absorbing dyes described above. Preferred are dyes such as cyanine dyes, squalirium dyes, oxonol dyes, pyrylium dyes, thiopyrylium dyes, polymethine dyes, oil soluble phthalocyanine dyes, triarylamine dyes, thiazolium dyes, oxazolium dyes, polyaniline dyes, polypyrrole dyes and polythiophene dyes.

Besides the above, pigments such as carbon black, titanium black, iron oxide powder, and colloidal silver can be preferably used. Cyanine dyes as dyes, and carbon black as pigments are especially preferred, in view of extinction coefficient, light-to-heat conversion efficiency and cost.

The addition amount of the light-to-heat conversion agent having an absorption band in a wavelength region of 700-1300 nm in the thermosensitive image formation layer depends on the absorption coefficient of the light-to-heat agent, but preferable is an addition amount where a planographic printing plate material has a reflection density of 0.3-3.0 in the case of the exposure light wavelength. Further preferable is an addition amount where the planographic printing plate material has a reflection density of 0.5-2.0. For example, in order to obtain the above reflection density, in the case of a cyanine dye, the addition amount of the cyanine dye in the image formation layer is 10-100 mg/m².

This light-to-heat conversion agent may also be contained in the image formation layer or in a layer adjacent thereto.

### {(b) Polymerization Initiator}

The polymerization initiator is a compound capable of initiating polymerization of an unsaturated monomer via laser exposure. Examples thereof include carbonyl compounds, organic sulfur compounds, peroxides, redox compounds, azo or diazo compounds, halides and photo-reducing dyes disclosed in J. Kosar, “Light Sensitive Systems”, Paragraph 5, and those disclosed in British Patent No. 1,459,563.

That is, examples of the polymerization initiator include the following compounds:

A benzoin derivative such as benzoin methyl ether, benzoin i-propyl ether, or α,α-dimethoxy-α-phenylacetophenone; a benzophenone derivative such as benzophenone, 2,4-dichlorobenzophenone, o-benzoyl methyl benzoate, or 4,4′-bis(dimethylamino)benzophenone; a thioxanthone derivative such as 2-chlorothioxanthone, 2-i-propylthioxanthone; an anthraquinone derivative such as 2-chloroanthraquinone or 2-methylanthraquinone; an acridone derivative such as N-methylacridone or N-butylacridone; α,α-diethoxyacetophenone; benzil; fluorenone; xanthone; an uranyl compound; a triazine derivative disclosed in Japanese Patent Publication Nos. 59-1281 and 61-9621 and Japanese Patent O.P.I. Publication No. 60-60104; an organic peroxide compound disclosed in Japanese Patent O.P.I. Publication Nos. 59-1504 and 61-243807; a diazonium compound in Japanese Patent Publication Nos. 43-23684, 44-6413, 44-6413, 47-1604 and U.S. Pat. No. 3,567,453; an organic azide compound disclosed in U.S. Pat. Nos. 2,848,328, 2,852,379 and 2,940,853; orthoquinondiazide compounds disclosed in Japanese Patent Publication Nos. 36-22062b, 37-13109, 38-18015 and 45-9610; various onium compounds disclosed in Japanese Patent Publication No. 55-39162, Japanese Patent O.P.I. Publication No. 59-14023 and “Macromolecules”, Volume 10, p. 1307 (1977); azo compounds disclosed in Japanese Patent Publication No. 59-142205; metal arene complexes disclosed in Japanese Patent O.P.I. Publication No. 1-54440, European Patent Nos. 109,851 and 126,712, and “Journal of Imaging Science”, Volume 30, p. 174 (1986); (oxo) sulfonium organoboron complexes disclosed in Japanese Patent O.P.I. Publication Nos. 4-56831 and 4-89535; titanocenes disclosed in Japanese Patent O.P.I. Publication Nos. 59-152396 and 61-151197; transition metal complexes containing a transition metal such as ruthenium disclosed in “Coordination Chemistry Review”, Volume 84, p. 85-277 (1988) and Japanese Patent O.P.I. Publication No. 2-182701; 2,4,5-triarylimidazol dimmer disclosed in Japanese Patent O.P.I. Publication No. 3-209477; carbon tetrabromide; organic halide compounds disclosed in Japanese Patent O.P.I. Publication No. 59-107344.

Furthermore, the following are cited as an example of a polymerization initiator. Compounds which can generate a radical disclosed in JP-A 2002-537419; polymerization initiators disclosed in Japanese Patent O.P.I. Publication Nos. 2001-175006, 2002-278057, and 2003-5363; onium salts which have two or more cation sections in the molecule disclosed in Japanese Patent O.P.I. Publication No. 2003-76010, N-nitrosamine compounds disclosed in Japanese Patent O.P.I. Publication No. 2001-133966; compounds which generate a radical with heat disclosed in Japanese Patent O.P.I. Publication No. 2001-343742, compounds which generate an acid or a radical with heat disclosed in JP-A No. 2002-6482; borates described in JP-A No. 2002-116539; compounds which generate an acid or a radical with heat disclosed in Japanese Patent O.P.I. Publication No. 2002-148790; photolytic or thermal polymerization initiators which have an unsaturated group of the polymerizable disclosed in Japanese Patent O.P.I. Publication No. 2002-207293; onium salts which have an anion of divalence or more as a counter ion disclosed in Japanese Patent O.P.I. Publication No. 2002-268217; sulfonyl sulfone compounds having a specified structure disclosed in Japanese Patent O.P.I. Publication No. 2002-328465; and compounds which generate a radical with heat disclosed in Japanese Patent O.P.I. Publication No. 2002-341519.

Specifically preferable compounds are an onium salt and a poly halogenated compound.

The following are cited as the onium salt. Diazonium salts disclosed in S. I. Schlesinger, Photogr. Sci. Eng., 18, 387 (1974), T. S. Bal et al., Polymer, 21, 423 (1980); ammonium salts disclosed in U.S. Pat. Nos. 4,069,055, 4,069,056, 4,027,992; phosphonium salts disclosed in D. C. Necker et al., Macromolecules, 17, 2468 (1984), C. S. Wen et al., The, Proc. Conf. Rad. Curing ASIA, p 478, Tokyo, October (1988), U.S. Pat. Nos. 4,069,055 and 4,069,056; iodonium salts disclosed in J. V. Crivello et al., Macromorecules, 10 (6), 1307 (1977), Chem. & amp, Eng. News, November 28, p 31 (1988), E.P. No. 104,143, and U.S. Pat. Nos. 339,049, 410,201, Japanese Patent O.P.I Publication Nos. 2-150848 and 2-296514; sulfonium salts disclosed in J. V. Crivello et al., Polymer J. 17, 73(1985), J. V. Crivello et al., J. Org. Chem., 43, 3055(1978), W. R. Watt et al., J. Polymer Sci., Polymer Chem. Ed., 22, 1789(1984), J. V. Crivello et al., Polymer Bull., 14, 279(1985), J. V. Crivello et al., Macromolecules, 14(5), 1141(1981), J. V. Crivello et al., J. Polymer Sci., Polymer Chem. Ed., 17, 2877(1979), EP Nos. 370,693, 3,902,114, 233,567, 297,443, 297,442, U.S. Pat. Nos. 4,933,377, 161,811, 410,201, 339,049, 4,760,013, 4,734,444, 2,833,827, DP Nos. 2,904,626, 3,604,580, and 3,604,581; selenonium salts disclosed in J. V. Crivello et al., Macromorecules, 10 (6), 1307 (1977), J. V. Crivello et al., J. Polymer Sci., and Polymer Chem. Ed., 17, 1047 (1979); and ammonium salts disclosed in C. S. Wen et al., Teh, Proc. Conf. Rad. Curing ASIA, p. 478 Tokyo, October (1988).

Among the above onium salts, iodonium salts and sulfonium salts are specifically preferred.

The preferred examples of the sulfonium salts are as follows: Triphenylsulfonium tetrafluoroborate, methyldiphenyl sulfonium tetrafluoroborate, dimethylphenylsulfonium hexafluorophosphate, 4-butoxyphenyldiphenylsulfonium tetrafluoroborate, 4-chlorophenyldiphenylsulfonium hexafluorophosphate, tri(4-phenoxylphenyl)sulfonium hexafluorophosphate, di(4-ethoxyphenyl)methylsulfonium hexafluoroarsenate, 4-acetonyl phenyldiphenylsulfonium tetrafluoroborate, 4-thiomehoxyphenyl diphenylsulfonium hexafluorophosphate, di(methoxysulfonylphenyl)methylsulfonium hexafluoroantimonate, di(nitrophenyl phenylsulfonium hexafluoroantimonate, di(carbomethoxyphenyl)methylsulfonium hexafluorophosphate, 4-acetamidophenyldiphenylsulfonium tetrafluoroborate, dimethylphenylsulfonium hexafluorophosphate, trifluoromethyldiphenylsulfonium tetrafluoroborate, p-(phenyl thiophenyl)diphenylsulfonium hexafluoroantimonate, 10-methyl phenoxathiinium hexafluorophosphate, 5-methylthianthrenium hexafluorophosphate, 10-phenyl-9,9-dimethylthioxanthenium hexafluorophosphate, triphenylsulfonium tetrakis (pentafluorophenyl)borate.

The preferred examples of the iodonium salts are as follows: Diphenyliodonium iodide, diphenyliodonium hexafluoroantimonate, 4-chlorophenyliodonium tetrafluoroborate, di(4-chlorophenyl)iodonium hexafluoroantimonate, diphenyliodonium hexafluorophosphate, diphenyliodonium trifluoroacetate, 4-trifluoromethylphenyl iodonium tetrafluoroborate, diphenyliodonium hexafluoroaresenate, ditolyliodonium hexafluorophosphate, di(4-methoxyphenyl)iodonium hexafluoroantimonate, di(4-methoxy phenyl)iodonium chloride, phenyl(4-methylphenyl)iodonium tetrafluoroborate, di(2,4-dimethyl phenyl)iodonium hexafluoroantimonate, di(4-t-butylphenyl)iodonium hexafluoroantimonate, 2,2′-diphenyliodonium hexafluorophosphate, tolylcumyl diphenyliodonium tetrakis(pentafluorophenyl)borate.

A polyhalogenated compound is a compound containing a trihalogenomethyl group, dihalogenomethyl group or a dihalogenomethylene group in the molecule. Preferable examples are halogenated compounds represented by the following Formula (1) and an oxadiazole compound with the above-described halogenated groups. Among these, a polyhaloacetyl compound represented by the following Formula (2) is especially preferred.

R¹—CY₂—(C═O)—R² Formula (1)

wherein R¹ represents a hydrogen atom, a halogen atom, an alkyl group, an aryl group, an acyl group, an alkylsulfonyl group, an arylsulfonyl group, an iminosulfonyl group or a cyano group; R² represents a monovalent substituent, provided that R¹ and R² may combine with each other to form a ring; and Y represents a halogen atom.

CY₃—(C═O)—X—R³ Formula (2)

wherein R³ represents a monovalent substituent; X represents —O— or —NR⁴—, in which R⁴ represents a hydrogen atom or an alkyl group, provided that R³ and R⁴ may combine with each other to form a ring; and Y represents a halogen atom. Among these, a compound having a polyhalogenated acetylamido group is preferably employed.

A compound having an oxadiazole ring with a polyhalogenated methyl group is also preferably used.

The addition amount of the polymerization initiator in the light sensitive layer is not specifically limited, but is preferably 0.1-20% by weight, and more preferably 0.8-15% by weight in the constituents of the light sensitive layer.

### {(c) Polymerizable Unsaturated Compound}

The polymerizable unsaturated compound is a compound having a polymerizable unsaturated group in the molecule. Usable examples thereof include conventional radically polymerizable monomers, and polyfunctional monomers and polyfunctional oligomers each having addition-polymerizable plural ethylenic double bonds in the molecule, which is ordinarily used in UV-curable resins.

The compound containing polymerizable ethylenic double bonds is not specifically limited, but preferred examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryloxyethyl acrylate, tetrahydrofurfuryloxyhexyl acrylate, or 1,3-dioxolanyl acrylate; a methacrylate, itaconate, crotonate or maleate alternative of the above acrylate; a bifunctional acrylate such as ethyleneglycol diacrylate, triethyleneglycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-ε-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-ε-caprolactone adduct or 1,6-hexanediol diglycidylether diacrylate; a dimethacrylate, diitaconate, dicrotonate or dimaleate alternative of the above diacrylate; a polyfunctional acrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-.ε-caprolactone adduct, pyrrogallol triacrylate, propionic acid dipentaerythritol triacrylate, propionic acid dipentaerythritol tetraacrylate, hydroxypivalylaldehyde modified dimethylolpropane triacrylate or EO-modified products thereof; and a methacrylate, itaconate, crotonate or maleate alternative of the above polyfunctional acrylate.

A prepolymer can be used as described above, and the prepolymer can be used singly, in combination with at least two kinds, or as an admixture of the above described monomers and/or oligomers.

Examples of the prepolymer include polyester (meth)acrylate obtained by incorporating (meth)acrylic acid in a polyester of a polybasic acid such as adipic acid, trimellitic acid, maleic acid, phthalic acid, terephthalic acid, hymic acid, malonic acid, succinic acid, glutaric acid, itaconic acid, pyromellitic acid, fumalic acid, pimelic acid, sebatic acid, dodecanic acid or tetrahydrophthalic acid with a polyol such as ethylene glycol, ethylene glycol, diethylene glycol, propylene oxide, 1,4-butane diol, triethylene glycol, tetraethylene glycol, polyethylene glycol, grycerin, trimethylol propane, pentaerythritol, sorbitol, 1,6-hexanediol or 1,2,6-hexanetriol; an epoxyacrylate such as bisphenol A•epichlorhydrin•(meth)acrylic acid or phenol novolak•epichlorhydrin•(meth)acrylic acid obtained by incorporating (meth)acrylic acid in an epoxy resin; an urethaneacrylate such as ethylene glycol-adipic acid•tolylenediisocyanate•2-hydroxyethylacrylate, polyethylene glycol•tolylenediisocyanate•2-hydroxyethylacrylate, hydroxyethylphthalyl methacrylate•xylenediisocyanate, 1,2-polybutadieneglycol•tolylenediisocyanate-2-hydroxyethylacrylate or trimethylolpropane•propylene glycol•tolylenediisocyanate•2-hydroxyethylacrylate, obtained by incorporating (meth)acrylic acid in an urethane resin; a silicone acrylate such as polysiloxane acrylate, or polysiloxane•diisocyanate•2-hydroxyethylacrylate; an alkyd modified acrylate obtained by incorporating a methacroyl group in an oil modified alkyd resin; and a spiran resin acrylate.

The image formation layer can contain a monomer such as a phosphazene monomer, triethylene glycol, an EO modified isocyanuric acid diacrylate, an EO modified isocyanuric acid triacrylate, dimethyloltricyclodecane diacrylate, trimethylolpropane acrylate benzoate, an alkylene glycol acrylate, or a urethane modified acrylate, or an addition polymerizable oligomer or prepolymer having a structural unit derived from the above monomer.

As a monomer used in combination in the image formation layer, there is a phosphate compound having at least one (meth)acryloyl group. The phosphate compound is a compound having a (meth)acryloyl group in which at least one hydroxyl group of phosphoric acid is esterified.

Besides the above compounds, compounds disclosed in Japanese Patent O.P.I. Publication Nos. 58-212994, 61-6649, 62-46688, 62-48589, 62-173295, 62-187092, 63-67189, and 1-244891, compounds described on pages 286 to 294 of “11290 Chemical Compounds” edited by Kagakukogyo Nipposha, and compounds described on pages 11 to 65 of “UV•EB Koka Handbook (Materials)” edited by Kobunshi Kankokai can be suitably used. Of these compounds, compounds having two or more acryl or methacryl groups in the molecule are preferable, and those having a molecular weight of not more than 10,000, and preferably not more than 5,000 are more preferable.

In the present invention, a monomer containing polymerizable ethylenic double bonds having a tertiary amino group in the molecule can be used preferably. The monomer is not specifically limited to the chemical structure, but is preferably a hydroxyl group-containing tertiary amine modified with glycidyl methacrylate, methacrylic acid chloride or acrylic acid chloride. Typically, a polymerizable compound is preferably used which is disclosed in Japanese Patent O.P.I. Publication Nos. 1-165613, 1-203413 and 1-197213.

In the present invention, a reaction product of a polyhydric alcohol having a tertiary amino group in the molecule, a diisocyanate, and a compound having both a hydroxyl group and an addition-polymerizable ethylenic double bond in the molecule is preferably used. A compound having a tertiary amino group and an amide bond in the molecule is specifically preferred.

Examples of the polyhydric alcohol having a tertiary amino group in the molecule include triethanolamine, N-methyldiethanolamine, N-ethyldiethanolamine, N-ethyldiethanolamine, N-n-butyldiethanolamine, N-tert-butyldiethanolamine, N,N-di(hydroxyethyl)aniline, N,N,N′,N′-tetra-2-hydroxypropylethylenediamine, p-tolyldiethanolamine, N,N,N′,N′-tetra-2-hydroxyethylethylenediamine, N,N-bis(2-hydroxypropyl)aniline, allyldiethanolamine, 3-dimethylamino-1,2-propane diol, 3-diethylamino-1,2-propane diol, N,N-di(n-propylamino)-2,3-propane diol, N,N-di(iso-propylamino)-2,3-propane diol, and 3-(N-methyl-N-benzylamino)-1,2-propane diol, but the present invention is not specifically limited thereto.

Examples of the diisocyanate include butane-1,4-diisocyanate, hexane-1,6-diisocyanate, 2-methylpentane-1,5-diisocyanate, octane-1,8-diisocyanate, 1,3-diisocyanatomethylcyclohexanone, 2,2,4-trimethylhexane-1,6-diisocyanate, isophorone diisocyanate, 1,2-phenylene diisocyanate, 1,3-phenylene diisocyanate, 1,4-phenylene diisocyanate, tolylene-2,4-diisocyanate, tolylene-2,5-diisocyanate, tolylene-2,6-diisocyanate, 1,3-di(isocyanatomethyl)benzene, and 1,3-bis(1-isocyanato-1-methylethyl)benzene, but the present invention is not specifically limited thereto.

Examples of the compound having a hydroxyl group and an addition-polymerizable ethylenic double bond in the molecule is not specifically limited, but 2-hydroxyethyl methacrylate, 2-hydroxyethyl acrylate, 4-hydroxybutyl acrylate, 2-hydroxypropylene-1,3-dimethacrylate, and 2-hydroxypropylene-1-methacrylate-3-acrylate are preferred.

The reaction product can be synthesized according to the same method as a conventional method in which a urethaneacrylate compound is ordinarily synthesized employing a diol, a diisocyanate and an acrylate having a hydroxyl group.

Examples of the reaction product of a polyhydric alcohol having a tertiary amino group in the molecule, a diisocyanate, and a compound having a hydroxyl group and an addition-polymerizable ethylenic double bond in the molecule are listed below.
M-1: A reaction product of triethanolamine (1 mole), hexane-1,6-diisocyanate (3 moles), and 2-hydroxyethyl methacrylate (3 moles)
M-2: A reaction product of triethanolamine (1 mole), isophorone diisocyanate (3 moles), and 2-hydroxyethyl methacrylate (3 moles)
M-3: A reaction product of N-n-butyldiethanolamine (1 mole), 1,3-bis(1-cyanato-1-methylethyl)benzene (2 moles), and 2-hydroxypropylene-1-methacrylate-3-acrylate (2 moles)
M-4: A reaction product of N-n-butyldiethanolamine (1 mole), 1,3-di(cyanatomethyl)benzene (2 moles), and 2-hydroxypropylene-1-methacrylate-3-acrylate (2 moles)
M-5: A reaction product of N-methydiethanolamine (1 mole), tolylene-2,4-diisocyanate (2 moles), and 2-hydroxypropylene-1,3-dimethacrylate (2 moles)
M-6: A reaction product of triethanolamine (1 mole), 1,3-bis(1-isocyanato-1-methylethyl)benzene (3 moles) and 2-hydroxyethyl methacrylate (3 moles)
M-7: A reaction product of ethylenediamine tetraethanol (1 mole), 1,3-bis(1-isocyanato-1-methylethyl)benzene (4 moles), and 2-hydroxyethyl methacrylate (4 moles)

In addition to the above, acrylates or methacrylates disclosed in Japanese Patent O.P.I. Publication Nos. 1-105238 and 2-127404 can be used.

The addition amount of the polymerizable unsaturated compound in the image formation layer is preferably 5-80% by weight, and more preferably 15-60% by weight.

The thermosensitive image formation layer containing the polymerizable composition described above preferably contains an alkali soluble polymer.

The alkali soluble polymer is a polymer having an acid value, and specifically, the copolymer having various structures as described below can be preferably used.

There are usable, as the above-described copolymer, an acrylic polymer, a polyvinylbutyral resin, polyurethane resin, polyamide resin, polyester resin, an epoxy resin, a phenol resin, a polycarbonate resin, polyvinyl butyral resin, polyvinyl formal resin, shellac and natural resins. These resins may be used in combination with at least two kinds.

Of these, a polymer having a hydroxyl group or a carboxyl group is preferably used, and a polymer having a carboxyl group is more preferably used.

Among these, preferable is a vinyl copolymer obtained via copolymerization of an acrylic monomer, and more preferable is a copolymer containing (a) a carboxyl group-containing monomer unit and (b) alkyl methacrylate or alkyl acrylate as the copolymerization monomer units.

Examples of the carboxyl group-containing monomer include an α,β-unsaturated carboxylic acid, for example, acrylic acid, methacrylic acid, maleic acid, maleic anhydride, itaconic acid, itaconic anhydride or a carboxylic acid such as a half ester of phthalic acid with 2-hydroxymethacrylic acid.

Examples of the alkyl methacrylate or alkyl acrylate include an unsubstituted alkyl ester such as methylmethacrylate, ethylmethacrylate, propylmethacrylate, butylmethacrylate, amylmethacrylate, hexylmethacrylate, heptylmethacrylate, octylmethacrylate, nonylmethacrylate, decylmethacrylate, undecylmethacrylate, dodecylmethacrylate, methylacrylate, ethylacrylate, propylacrylate, butylacrylate, amylacrylate, hexylacrylate, heptylacrylate, octylacrylate, nonylacrylate, decylacrylate, undecylacrylate, or dodecylacrylate; a cyclic alkyl ester such as cyclohexyl methacrylate or cyclohexyl acrylate; and a substituted alkyl ester such as benzyl methacrylate, 2-chloroethyl methacrylate, N,N-dimethylaminoethyl methacrylate, glycidyl methacrylate, benzyl acrylate, 2-chloroethyl acrylate, N,N-dimethylaminoethyl acrylate or glycidyl acrylate.

Those derived from monomers described in the following items (1)-(14) are also usable as other copolymerization monomers.

(1) A monomer having an aromatic hydroxy group, for example, o-, (p- or m-) hydroxystyrene, or o-, (p- or m-) hydroxyphenylacrylate.

(2) A monomer having an aliphatic hydroxy group, for example, 2-hydroxyethyl acrylate, 2-hydroxyethyl methacrylate, N-methylolacrylamide, N-methylolmethacrylamide, 4-hydroxybutyl acrylate, 4-hydroxybutyl methacrylate, 5-hydroxypentyl acrylate, 5-hydroxypentyl methacrylate, 6-hydroxyhexyl acrylate, 6-hydroxyhexyl methacrylate, N-(2-hydroxyethyl)acrylamide, N-(2-hydroxyethyl)methacrylamide, or hydroxyethyl vinyl ether.

(3) A monomer having an aminosulfonyl group, for example, m- or p-aminosulfonylphenyl methacrylate, m- or p-aminosulfonylphenyl acrylate, N-(p-aminosulfonylphenyl) methacrylamide, or N-(p-aminosulfonylphenyl)acrylamide.

(4) A monomer having a sulfonamido group, for example, N-(p-toluenesulfonyl)acrylamide, or N-(p-toluenesulfonyl)-methacrylamide.

(5) An acrylamide or methacrylamide, for example, acrylamide, methacrylamide, N-ethylacrylamide, N-hexylacrylamide, N-cyclohexylacrylamide, N-phenylacrylamide, N-nitrophenylacrylamide, N-ethyl-N-phenylacrylamide, N-4-hydroxyphenylacrylamide, or N-4-hydroxyphenylmethacrylamide.

(6) A monomer having a fluorinated alkyl group, for example, trifluoromethyl acrylate, trifluoromethyl methacrylate, tetrafluoropropyl methacrylate, hexafluoropropyl methacrylate, octafluoropentyl acrylate, octafluoropentyl methacrylate, heptadecafluorodecyl methacrylate, heptadecafluorodecyl methacrylate, or N-butyl-N-(2-acryloxyethyl)heptadecafluorooctylsulfonamide.

(7) A vinyl ether, for example, ethyl vinyl ether, 2-chloroethyl vinyl ether, propyl vinyl ether, butyl vinyl ether, octyl vinyl ether, or phenyl vinyl ether

(8) A vinyl ester, for example, vinyl acetate, vinyl chroloacetate, vinyl butyrate, or vinyl benzoate.

(9) A styrene, for example, styrene, methylstyrene, or chloromethystyrene.

(10) A vinyl ketone, for example, methyl vinyl ketone, ethyl vinyl ketone, propyl vinyl ketone, or phenyl vinyl ketone.

(11) An olefin, for example, ethylene, propylene, isobutylene, butadiene, or isoprene.

(12) N-vinylpyrrolidone, N-vinylcarbazole, or N-vinylpyridine.

(13) A monomer having a cyano group, for example, acrylonitrile, methacrylonitrile, 2-pentenenitrile, 2-methyl-3-butene nitrile, 2-cyanoethyl acrylate, or o-, m- or p-cyanostyrene.

(14) A monomer having an amino group, for example, N,N-diethylaminoethyl methacrylate, N,N-dimethylaminoethyl acrylate, N,N-dimethylaminoethyl methacrylate, polybutadiene urethane acrylate, N,N-dimethylaminopropyl acrylamide, N,N-dimethylacrylamide, acryloylmorpholine, N-i-propylacrylamide, or N,N-diethylacrylamide.

Further, another monomer may be copolymerized with the above monomer.

An unsaturated bond-containing copolymer, which is obtained by reacting the polymer having a carboxyl group with for example, a compound having a (meth)acryloyl group and an epoxy group, is also preferred.

Examples of the compound having a (meth)acryloyl group and an epoxy group in the molecule include glycidyl acrylate, glycidyl methacrylate and an epoxy group-containing unsaturated compound disclosed in Japanese Patent O.P.I. Publication No. 11-27196.

Of the above alkali soluble polymers, those having an acid value of 30-200 are preferred. Of these, those having a weight average molecular weight of 15,000-500,000 are preferred.

Of the above polymers, those having a polymerizable unsaturated group are preferred, and those having 5-50 mol % of the polymerizable unsaturated group as a repeating unit of the entire polymer are specifically preferred.

An alkali soluble polymer having a polymerizable unsaturated group can be synthesized according to a conventional method with no limitation.

For example, a method can be used which reacts a carboxyl group with a glycidyl group, or reacts a hydroxyl group with an isocyanate group.

Typically, the alkali soluble polymer is a reaction product obtained by reacting a copolymer having a carboxyl group-containing monomer unit with an aliphatic epoxy-containing unsaturated compound such as allyl glycidyl ether, glycidyl(meth)acrylate, α-ethylglycidyl(meth)acrylate, glycidyl crotonate, glycidyl isocrotonate, crotonyl glycidyl ether, itaconic acid monoalkylmonoglycidyl ester, fumaric acid monoalkylmonoglycidyl ester, or maleic acid monoalkylmonoglycidyl ester; or an alicyclic epoxy-containing unsaturated compound such as 3,4-epoxycyclohexylmethyl(meth)acrylate. In the present invention, when an amount of the carboxyl group reacted with the epoxy-containing unsaturated compound is represented in terms of mol %, The amount is preferably 5-50 mol %, and more preferably 10-30 mol % in view of sensitivity and printing durability.

Reaction of a copolymer having a carboxyl group-containing monomer unit with a compound having an epoxy group and an unsaturated group is carried out for example, at 80-120° C. for 1-50 hours. The reaction product can be synthesized according to a conventional polymerization method, for example, a method described in literatures such as W. R. Sorenson & T. W. Cambell “Kobunshi Gosei Jikkenho” published by TOKYO KAGAKU DOHJIN, or Japanese Patent O.P.I. Publication Nos. 10-315598 and 11-271963, or a method similar to the above.

The addition amount of the alkali soluble polymer in the image formation layer is preferably 10-90% by weight, more preferably 15-70% by weight, and still more preferably 20-50% by weight.

Examples of the copolymer having a carboxyl group-containing monomer unit described above include a copolymer having at least one selected from units derived from the following monomers (1)-(17).

(1) A monomer having an aromatic hydroxy group;

(2) A monomer having an aliphatic hydroxy group;

(3) A monomer having an aminosulfonyl group;

(4) A monomer having a sulfonamido group;

(5) An α,β-unsaturated carboxylic acid;

(6) A substituted or unsubstituted alkyl acrylate;

(7) A substituted or unsubstituted alkyl acrylate;

(8) Acrylamide or methacrylamide;

(9) A monomer having a fluorinated alkyl group;

(10) A vinyl ether;

(11) A vinyl ester;

(12) A styrene;

(13) A vinyl ketone;

(14) An olefin;

(15) N-vinylpyrrolidone, N-vinylcarbazole, or N-vinylpyridine;

(16) A monomer having a cyano group; and

(17) A monomer having an amino group.

Typical examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryloxyethyl acrylate, tetrahydrofurfuryloxyhexyl acrylate, or 1,3-dioxolanyl acrylate; a methacrylate, itaconate, crotonate or maleate alternative of the above acrylate; a bifunctional acrylate such as ethyleneglycol diacrylate, triethyleneglycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-ε-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-ε-caprolactone adduct or 1,6-hexanediol diglycidylether diacrylate; a dimethacrylate, diitaconate, dicrotonate or dimaleate alternative of the above diacrylate; a polyfunctional acrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-.ε-caprolactone adduct, pyrrogallol triacrylate, propionic acid dipentaerythritol triacrylate, propionic acid dipentaerythritol tetraacrylate or hydroxypivalylaldehyde modified dimethylolpropane triacrylate; a methacrylate, itaconate, crotonate or maleate alternative of the above polyfunctional acrylate.

### (Polymeric Binder)

The above-described thermosensitive image formation layer can contain a polymeric binder.

Examples of the polymeric binder include a polyacrylate resin, a polyvinylbutyral resin, a polyurethane resin, a polyamide resin, a polyester resin, an epoxy resin, a phenol resin, a polycarbonate resin, a polyvinyl butyral resin, a polyvinyl formal resin, a shellac resin, or another natural resin. These polymeric binder can be used as an admixture of at least two kinds.

### (Polymerization Inhibitor)

The above-described thermosensitive image formation layer can optionally contain a polymerization inhibitor.

As the polymerization inhibitor, there is for example, a hindered amine with a base dissociation constant (pKb) of 7-14 having a piperidine moiety.

The polymerization inhibitor addition amount is preferably 0.001-10% by weight, more preferably 0.01-10% by weight, and still more preferably 0.1-5% by weight, based on the polymerizable-unsaturated group-containing compound.

The above-described thermosensitive image formation layer may contain a second polymerization inhibiter other than the above-described polymerization inhibiter. Examples of the second polymerization inhibiter include hydroquinone, p-methoxyphenol, di-t-butyl-p-cresol, pyrrogallol, t-butylcatechol, benzoquinone, 4,4′-thiobis (3-methyl-6-t-butylphenol), 2,2′-methylenebis(4-methyl-6-t-butylphenol), N-nitrosophenylhydroxylamine cerous salt, and 2-t-butyl-6-(3-t-butyl-6-hydroxy-5-methylbenzyl)-4-methylphenyl acrylate.

The above-described thermosensitive image formation layer can contain a colorant. As the colorant can be used known materials including commercially available materials. Examples of the colorant include those described in revised edition “Ganryo Binran”, edited by Nippon Ganryo Gijutu Kyoukai (publishe by Seibunndou Sinkosha), or “Color Index Binran”. As the colorant, there are pigments.

As kinds of the pigments, there are black pigment, yellow pigment, red pigment, brown pigment, violet pigment, blue pigment, green pigment, fluorescent pigment, and metal powder pigment. Typical examples of the pigments include inorganic pigment (such as titanium dioxide, carbon black, graphite, zinc oxide, Prussian blue, cadmium sulfide, iron oxide, or chromate of lead, zinc, barium or calcium); and organic pigment (such as azo pigment, thioindigo pigment, anthraquinone pigment., anthanthrone pigment, triphenedioxazine pigment, vat dye pigment, phthalocyanine pigment or its derivative, or quinacridone pigment).

Among these pigments, pigment is preferably used which does not substantially have absorption in the absorption wavelength regions of a spectral sensitizing dye used according to a laser for exposure. The absorption of the pigment used is not more than 0.05, obtained from the reflection spectrum of the pigment measured employing an integrating sphere and employing light with the wavelength of the laser used. The pigment addition amount is preferably 0.1-10% by weight, and more preferably 0.2-5% by weight, based on the solid content of the above-described constituent.

A protective layer is preferably provided on the thermosensitive image formation layer. It is preferred that the protective layer (oxygen shielding layer) is highly soluble in a developer as described later (generally an alkaline solution). The protective layer preferably contains polyvinyl alcohol and polyvinyl pyrrolidone. Polyvinyl alcohol has the effect of preventing oxygen from transmitting and polyvinyl pyrrolidone has the effect of increasing adhesion between the oxygen shielding layer and the image formation layer adjacent thereto.

Besides the above two polymers, the oxygen shielding layer may contain a water soluble polymer such as polysaccharide, polyethylene glycol, gelatin, glue, casein, hydroxyethyl cellulose, carboxymethyl cellulose, methyl cellulose, hydroxyethyl starch, gum arabic, sucrose octacetate, ammonium alginate, sodium alginate, polyvinyl amine, polyethylene oxide, polystyrene sulfonic acid, polyacrylic acid, or a water soluble polyamide.

The above-described polymerizable image formation layer in the present invention is an image formation layer containing a polymerization initiator and a polymerizable unsaturated compound. As the polymerization initiator and polymerizable unsaturated compound, the same as those used in the thermosensitive image formation layer containing a polymerizable composition described above can be used.

As a photopolymerization initiator in the polymerizable image formation layer, a titanocene compound, a triarylmonoalkylborate compound, an iron-arene complex or a trihaloalkyl compound is preferably used.

As the titanocene compounds, there are compounds disclosed in Japanese Patent O.P.I. Publication Nos. 63-41483 and 2-291. Preferred examples thereof include bis(cyclopentadienyl)-Ti-dichloride, bis(cyclopentadienyl)-Ti-bisphenyl, bis(cyclopentadienyl)-Ti-bis-2,3,4,5,6-pentafluorophenyl, bis(cyclopentadienyl)-Ti-bis-2,3,5,6-tetrafluorophenyl, bis(cyclopentadienyl)-Ti-bis-2,4,6-trifluorophenyl, bis(cyclopentadienyl)-Ti-bis-2,6-difluorophenyl, bis(cyclopentadienyl)-Ti-bis-2,4-difluorophenyl, bis(methylcyclopentadienyl)-Ti-bis-2,3,4,5,6-pentafluorophenyl, bis(methylcyclopentadienyl)-Ti-bis-2,3,5,6-tetrafluorophenyl, bis(methylcyclopentadienyl)-Ti-bis-2,4-difluorophenyl (IRUGACURE 727L, produced by Ciba Specialty Co., Ltd.), bis(cyclopentadienyl)-bis(2,6-difluoro-3-(pyry-1-yl)phenyl) titanium (IRUGACURE 784, produced by Ciba Specialty Co., Ltd.), bis(cyclopentadienyl)-bis(2,4,6-trifluoro-3-(pyry-1-yl)phenyl) titanium, and bis(cyclopentadienyl)-bis(2,4,6-trifluoro-3-(2,5-dimethylpyry-1-yl)phenyl)titanium.

As the monoalkyltriaryl borate compounds, there are those described in Japanese Patent O.P.I. Publication Nos. 62-150242 and 62-143044. Preferred examples of the monoalkyl-triaryl borate compounds include tetra-n-butyl ammonium n-butyl-trinaphthalene-1-yl-borate, tetra-n-butyl ammonium n-butyl-triphenyl-borate, tetra-n-butyl ammonium n-butyl-tri-(4-tert-butylphenyl)-borate, tetra-n-butyl ammonium n-hexyl-tri-(3-chloro-4-methylphenyl)-borate, and tetra-n-butyl ammonium n-hexyl-tri-(3-fluorophenyl)-borate.

As the iron arene complexes, there are those described in Japanese Patent O.P.I. Publication No. 59-219307. Preferred examples of the iron arene complex include η-benzene-(η-cyclopentadienyl)iron•hexafluorophosphate, η-cumene)-(η-cyclopentadienyl)iron•hexafluorophosphate, η-fluorene-(η-cyclopentadienyl)iron•hexafluorophosphate, η-naphthalene-(η-cyclopentadienyl)iron•hexafluorophosphate, η-xylene-(η-cyclopentadienyl)iron•hexafluorophosphate, and η-benzene-(η-cyclopentadienyl)iron•hexafluoroborate.

As the trihaloalkyl compound, the trihaloalkyl compound described above can be used.

Any other polymerization initiator can also be used in combination.

As the polymerization initiator, there are, for example, cumarin derivatives B-1 through B-22 disclosed in Japanese Patent O.P.I. Publication No. 8-129253, cumarin derivatives D-1 through D-32 disclosed in Japanese Patent O.P.I. Publication No. 2003-121901, cumarin derivatives 1 through 21 disclosed in Japanese Patent O.P.I. Publication No. 2002-363206, cumarin derivatives 1 through 40 disclosed in Japanese Patent O.P.I Publication No. 2002-363207, cumarin derivatives 1 through 34 disclosed in Japanese Patent O.P.I. Publication No. 2002-363208, and cumarin derivatives 1 through 56 disclosed in Japanese Patent O.P.I. Publication No. 2002-363209.

### (Photosensitizing Dyes)

A sensitizing dye used in the photopolymerizable image formation layer is preferably one having the absorption maximum in the vicinity of the wavelength of light emitted from a light source employed.

Examples of the sensitizing dyes, which have sensitivity to the wavelengths of visible to near infrared regions, i.e., have an absorption maximum in the wavelength ranges of 350-1300 nm, include cyanines, phthalocyanines, merocyanines, porphyrins, spiro compounds, ferrocenes, fluorenes, fulgides, imidazoles, perylenes, phenazines, phenothiazines, polyenes, azo compounds, diphenylmethanes, triphenylmethanes, polymethine acridines, cumarines, ketocumarines, quinacridones, indigos, styryl dyes, pyrylium dyes, pyrromethene dyes, pyrazolotriazole compounds, benzothiazole compounds, barbituric acid derivatives, thiobarbituric acid derivatives, ketoalcohol borate complexes, and compounds disclosed in European Patent No. 568,993, U.S. Pat. Nos. 4,508,811 and 5,227,227, and Japanese Patent O.P.I. Publication Nos 2001-125255 and 11-271969.

Specific examples of the above-described photopolymerization initiator in combination with the sensitizing dye are disclosed in Japanese Patent O.P.I. Publication Nos. 2001-125255 and 11-271969.

The amount of sensitizing dye added into the image formation layer is preferably an amount giving a reflection density of the printing plate surface of 0.1-1.2 at a wavelength of an exposure light source. The sensitizing dye content giving such an amount of the image formation layer is ordinarily 0.5-10% by weight, though depending on molecular extinction coefficient of each dye or crystallinity in the image formation layer.

The polymerizable image formation layer may contain the foregoing polymer binder as a polymer binder.

### (Various Additives)

The polymerizable image formation layer of the present invention may contain a hindered phenol compound, a hindered amine compound or other polymerization inhibitors in addition to the compounds described above, in order to prevent undesired polymerization of the ethylenically unsaturated monomer containing a double bond during preparation or storage of the light sensitive planographic printing plate material.

Examples of the hindered phenol compound include 2,6-di-t-butyl-p-cresol, butylhydroxyanisole, 2,2′-methylenebis(4-methyl-6-t-butylphenol), 4,4′-butylidenebis(3-methyl-6-t-butylphenol), tetrakis[methylene-3-(3′,5′-t-butyl-4′-hydroxyphenyl)-propionate]methane, bis[3,3′-bis(4′-hydroxy-3′-t-butylphenyl)butyric acid]glycol ester, 2-t-butyl-6-(3-t-butyl-2-hydroy-5-methylbenzyl)-4-methylphenyl acrylate, and 2-[1-(2-hydroxy-3,5-di-t-pentylphenyl)ethyl]-4,6-di-t-pentylphenyl acrylate. Among them, 2-t-butyl-6-(3-t-butyl-2-hydroy-5-methylbenzyl)-4-methylphenyl acrylate and 2-[1-(2-hydroxy-3,5-di-t-pentylphenyl)ethyl]-4,6-di-t-pentylphenyl acrylate, each having a (meth)acryloyl group, are preferred.

Examples of the hindered amine compound include bis(1,2,2,6,6-pentamethyl-4-piperidyl)sebacate, bis(2,2,6,6-tetramethyl-4-piperidyl)sebacate, 1-[2-{3-(3,5-di-t-butyl-hydroxyphenyl)propionyloxy}ethyl]-4-[2-{3-(3,5.-di-t-butyl-hydroxyphenyl)propionyloxy}ethyl]-2,2,6,6-tetramethylpiperidine, 4-benzoyloxy-2,2,6,6-tetramethylpiperidine, and 8-acetyl-3-dodecyl-7,7,9,9-tetramethyl-1,3,8-triazaspiro-[4.5]decane-2,4-dione.

Examples of another polymerization inhibitor include hydroquinone, p-methoxyphenol, di-t-butyl-p-cresol, pyrrogallol, t-butylcatechol, benzoquinone, 4,4′-thiobis(3-methyl-6-t-butylphenol), 2,2′-methylenebis(4-methyl-6-t-butylphenol), N-nitrosophenylhydroxylamine cerous salt, and hindered amines such as 2,2,6,6-tetramethylpiperidine derivatives-butyl-6-(3-t-butyl-6-hydroxy-5-methylbenzyl)-4-methylphenyl acrylate.

The polymerization inhibitor addition amount is preferably 0.01-5% by weight based on the total solid content of the above-described composition. Further, in order to prevent polymerization induced by oxygen, a higher fatty acid such as behenic acid or a higher fatty acid derivative such as behenic amide may be added to the photopolymerizable light sensitive layer, or may be localized on the surface of the photopolymerizable light sensitive layer in the course of drying after coating. The higher fatty acid or higher fatty acid derivative addition amount is preferably 0.5-10% by weight based on the total solid content of the composition.

The polymerizable image formation layer can further contain a colorant similarly to the above-described in addition to the above-described composition.

### (Coating)

Examples of solvents used during preparation of the image formation layer coating solution in the present invention include an alcohol such as sec-butanol, isobutanol, n-hexanol, or benzyl alcohol; a polyhydric alcohol such as diethylene glycol, triethylene glycol, tetraethylene glycol, or 1,5-pentanediol; an ether such as propylene glycol monobutyl ether, dipropylene glycol monomethyl ether, or tripropylene glycol monomethyl ether; a ketone or aldehyde such as diacetone alcohol, cyclohexanone, or methyl cyclohexanone; and an ester such as ethyl lactate, butyl lactate, diethyl oxalate, or methyl benzoate.

The resulting coating composition (image formation layer coating solution) is coated on a support according to a conventional method, and dried to obtain a photopolymerizable light sensitive planographic printing plate material. Examples of the coating method include an air doctor coating method, a blade coating method, a wire bar coating method, a knife coating method, a dip coating method, a reverse roll coating method, a gravure coating method, a cast coating method, a curtain coating method, and an extrusion coating method.

The drying temperature of the light sensitive layer is preferably 60-160° C., more preferably 80-140° C., and still more preferably 90-120° C.

### (Protective Layer)

A protective layer is preferably provided on the image formation layer of the present invention. It is preferred that the protective layer (oxygen shielding layer) is highly soluble in a developer (generally an alkaline solution).

Materials constituting the protective layer are preferably polyvinyl alcohol, polysaccharide, polyvinyl pyrrolidone, polyethylene glycol, gelatin, glue, casein, hydroxyethyl cellulose, carboxymethyl cellulose, methyl cellulose, hydroxyethyl starch, gum arabic, sucrose octacetate, ammonium alginate, sodium alginate, polyvinyl amine, polyethylene oxide, polystyrene sulfonic acid, polyacrylic acid, or a water soluble polyamide. These materials may be used singly or in combination. Specifically preferred material is polyvinyl alcohol.

A coating composition for the protective layer is obtained by dissolving the above-described material in an appropriate solvent. The coating solution is coated on the photopolymerizable light sensitive layer and dried to form a protective layer. The dry thickness of the protective layer is preferably 0.1-5.0 μm, and more preferably 0.5-3.0 μm. The protective layer may contain a surfactant or a matting agent, if desired.

The commonly known coating method for coating of the above-described light sensitive layer is also utilized as the protective layer coating method. The drying temperature of the protective layer is preferably lower than that of the light sensitive layer. The drying temperature difference between the protective layer and the light sensitive layer is preferably at least 10° C., and more preferably at least 20° C. The upper limit of the drying temperature difference is at most 50° C.

Further, the drying temperature of the protective layer is preferably lower than glass transition temperature (Tg) of the binder contained in the light sensitive layer. The temperature difference between the drying temperature of the protective layer and Tg of the binder contained in the light sensitive layer is preferably at least 20° C., and more preferably at least 40° C. The upper limit of the temperature difference is at most 60° C.

### (Plate-Making and Printing)

The light sensitive planographic printing plate material of the present invention is imagewise exposed to form an image, and then optionally developed to obtain a printing plate utilized for printing.

Examples of light sources for the imagewise exposure include a laser, an emission diode, a xenon flush lamp, a halogen lamp, a carbon arc light, a metal halide lamp, a tungsten lamp, a high pressure mercury lamp, and a non-electrode light source.

In the case of light exposure at one time, a mask material obtained by forming a negative pattern of a desired exposure image with a light shielding material may be placed on the photopolymerizable light sensitive layer to conduct light exposure.

When an array type light source such as a light emitting diode array or the like is used, or exposure employing a halogen lamp, a metal halide lamp or a tungsten lamp is controlled with an optical shutter material such as liquid crystal or PLZT, a digital exposure according to an image signal is possible and preferable. In this case, direct writing is possible without using any mask material.

In the case of laser exposure, which can be condensed in the beam form, scanning exposure according to an image can be carried out, and direct writing is possible without using any mask material. When the laser is employed for imagewise exposure, a highly dissolved image can be obtained, since it is easy to condense its exposure spot in minute size.

A laser scanning method by means of a laser beam includes a method of scanning on an outer surface of a cylinder, a method of scanning on an inner surface of a cylinder and a method of scanning on a plane. In the method of scanning on an outer surface of a cylinder, laser beam exposure is conducted while a drum around which a recording material is wound is rotated, in which main scanning is represented by the rotation of the drum, while sub-scanning is represented by the movement of the laser beam. In the method of scanning on an inner surface of a cylinder, a recording material is fixed on the inner surface of a drum, a laser beam is emitted from the inside, and main scanning is carried out in the circumferential direction by rotating a part of or an entire part of an optical system, while sub-scanning is carried out in the axial direction by moving straight a part of or an entire part of the optical system in parallel with a shaft of the drum. In the method of scanning on a plane, main scanning by means of a laser beam is carried out through a combination of a polygon mirror, a galvano mirror and an fθ lens, and sub-scanning is carried out by moving a recording medium. The method of scanning on an outer surface of a cylinder, and the method of scanning on an inner surface of a cylinder are preferred in optical system accuracy and high density recording.

When the light sensitive planographic printing plate material is to be subjected to a development treatment, an automatic developing machine is ordinarily used.

Printing is carried out employing a conventional printing press.

In recent years, printing ink containing no petroleum volatile organic compound (VOC) has been developed and used in view of environmental protection, but the present invention produes excellent effects in employing such a printing ink for environmental protection. Examples of the printing ink for environmental protection include soybean oil ink “Naturalith 100” produced by Dainippon Ink Kagaku Kogyo Co., Ltd., VOC zero ink “TK HIGH ECO NV” produced by Toyo Ink Manufacturing Co., Ltd., process ink “Soycelvo” produced by Tokyo Printing Ink MFG. Co., Ltd., and so forth.

### Example

Next, the present invention will now be described in detail referring to examples, but embodiments of the present invention are not limited thereto. Incidentally, “parts” in the description represents “parts by weight”, unless otherwise specifically mentioned.

### Example 1

### (Preparation of Supports 1-20)

Each of the utilized aluminum plates having a thickness of 0.3 mm has the composition shown in Table 1 (the rest unshown in Table 1: aluminum and unavoidable impurities).

TABLE 1

| Aluminum | Composition (% by weight) | | | | | | | | | | Total | |
|---|---|---|---|---|---|---|---|---|---|---|---|---|
| plate No. | Na | Mg | Si | Ti | Mn | Fe | Ni | Cu | Zn | Ga | amount | Remarks |
| A | 0.003 | 0.200 | 0.081 | 0.006 | 0.004 | 0.320 | 0.004 | 0.003 | 0.015 | 0.0070 | 0.64 | Present |
| | | | | | | | | | | | | invention |
| B | 0.003 | 0.085 | 0.081 | 0.006 | 0.004 | 0.320 | 0.004 | 0.003 | 0.015 | 0.0070 | 0.53 | Comparative |
| | | | | | | | | | | | | example |
| C | 0.003 | 0.410 | 0.081 | 0.006 | 0.004 | 0.320 | 0.004 | 0.003 | 0.015 | 0.0070 | 0.85 | Comparative |
| | | | | | | | | | | | | example |
| D | 0.003 | 0.200 | 0.081 | 0.006 | 0.004 | 0.320 | 0.004 | 0.003 | 0.015 | 0.0008 | 0.64 | Comparative |
| | | | | | | | | | | | | example |
| E | 0.003 | 0.200 | 0.081 | 0.006 | 0.004 | 0.320 | 0.004 | 0.003 | 0.015 | 0.0210 | 0.66 | Comparative |
| | | | | | | | | | | | | example |

Aluminum plates were subjected to an alkali etching step, an electrolytic surface-roughening step, and an alkali etching step or a phosphoric acid-desmutting step after the electrolytic surface-roughening treatment under the conditions shown in Table 2 and Table 3.

### (Alkali Etching)

The aluminum plate was immersed in an aqueous 4% sodium hydroxide solution maintained at 50° C. for 30 seconds to conduct an etching treatment, and washed with water.

The aluminum plate which was subjected to this etching treatment was immersed in an aqueous 5% nitric acid solution maintained at 25° C. for 10 seconds for neutralization, and was subsequently washed with water. The dissolution amount of the surface generated via etching was 3 g/m².

### (Electrolytic Surface-Roughening)

The electrolytic surface-roughening step was conducted under the conditions shown in Table 2 and Table 3.

(Alkali Etching Treatment after each Electrolytic Treatment)

The aluminum plate was immersed in an aqueous 2% sodium hydroxide solution maintained at 50° C. for 20 seconds to conduct an etching treatment, and washed with water.

The aluminum plate which was subjected to this etching treatment was immersed in an aqueous 5% nitric acid solution maintained at 25° C. for 10 seconds for neutralization, and was subsequently washed with water. The dissolution amount of the surface generated via etching was 1.2 g/m².

(Phosphoric Acid-Desmutting Treatment after each Electrolytic Treatment)

The aluminum plate was immersed in 75 g/l of an aqueous phosphoric acid solution maintained at 55° C. for 12 seconds to conduct a desmutting treatment, and washed with water. The dissolution amount of the aluminum plate surface generated via the desmutting treatment was 0.9 g/m².

Subsequently, employing direct current, the resulting aluminum plate was subjected to an anodizing treatment in a 25° C. aqueous solution having a sulfuric acid concentration of 200 g/l and a dissolved aluminum concentration of 1.5 g/l at a current density of 5 A/dm² to form an anodization film weight of 30 mg/dm², and washed with distilled water.

Subsequently, the anodized aluminum plate was dipped in a 0.2% aqueous polyvinyl phosphonic acid solution at 60° C. for 40 seconds, washed with distilled water, and dried for 30 seconds employing 150° C. air to prepare supports 1-20.

The arithmetic average roughness of each of the support surfaces is shown in Table 3.

### {Measurement of Arithmetic Average Roughness (Ra)}

The arithmetic average roughness (Ra) of the surface of the resulting support was two-dimensionally measured five times according to IS04287, employing a contact-type roughness meter SE 1700α produced by Kosaka Laboratory Ltd., and an average thereof defined as the arithmetic average roughness was obtained. The two-dimensional surface roughness measurement was conducted under the following conditions:

Cutoff: 0.8 mm

Measured length: 4 mm

Scanning speed: 0.1 mm/second

Stylus tip diameter: 2 μm

TABLE 2

| | | | First electrolytically surface-roughening treatment condition | | | | | | | | |
|---|---|---|---|---|---|---|---|---|---|---|---|
| | | Alkali | Electrolyte | | | | | | | | |
| | | etching | Hydro- | | | | | | | | |
| | | (Conducted | chloric | Nitric | Al | Acetic | | Current | Electrolytic | Quantity of | |
| | Aluminum | or Not | acid | acid | iron | acid | Temperature | density | time | electricity | |
| Support | plate No. | conducted) | (g/l) | (g/l) | (g/l) | (g/l) | (° C.) | (A/dm²) | (sec) | (c/dm²) | *1 |
| 1 | A | Conducted | 11 | | 8 | 10 | 30 | 65 | 10 | 650 | *2 |
| 2 | A | Conducted | 11 | | 8 | 10 | 30 | 65 | 10 | 650 | *3 |
| 3 | A | Conducted | | 11 | 8 | 10 | 30 | 30 | 15 | 450 | *2 |
| 4 | A | Conducted | | 11 | 8 | 10 | 30 | 30 | 15 | 450 | *3 |
| 5 | A | ** | 11 | | 8 | 10 | 30 | 65 | 10 | 650 | *2 |
| 6 | A | ** | 11 | | 8 | 10 | 30 | 65 | 10 | 650 | *3 |
| 7 | A | ** | | 11 | 8 | 10 | 30 | 30 | 15 | 450 | *2 |
| 8 | A | ** | | 11 | 8 | 10 | 30 | 30 | 15 | 450 | *3 |
| 9 | A | Conducted | 11 | | 8 | 10 | 30 | 65 | 15 | 975 | *2 |
| 10 | A | Conducted | 11 | | 8 | 10 | 30 | 65 | 15 | 975 | *3 |
| 11 | A | Conducted | | 11 | 8 | 10 | 30 | 45 | 20 | 900 | *2 |
| 12 | A | Conducted | | 11 | 8 | 10 | 30 | 45 | 20 | 900 | *3 |
| 13 | B | Conducted | 11 | | 8 | 10 | 30 | 65 | 10 | 650 | *2 |
| 14 | B | Conducted | 11 | | 8 | 10 | 30 | 65 | 10 | 650 | *3 |
| 15 | C | Conducted | 11 | | 8 | 10 | 30 | 65 | 10 | 650 | *2 |
| 16 | C | Conducted | 11 | | 8 | 10 | 30 | 65 | 10 | 650 | *3 |
| 17 | D | Conducted | 11 | | 8 | 10 | 30 | 65 | 10 | 650 | *2 |
| 18 | D | Conducted | 11 | | 8 | 10 | 30 | 65 | 10 | 650 | *3 |
| 19 | E | Conducted | 11 | | 8 | 10 | 30 | 65 | 10 | 650 | *2 |
| 20 | E | Conducted | 11 | | 8 | 10 | 30 | 65 | 10 | 650 | *3 |

*1: Treatment after first electrolytically surface-roughening treatment
*2: Alkali etching treatment,
*3: Phosphoric acid-desmutting treatment,
**: Not conducted

TABLE 3

| | Second electrolytically surface-roughening treatment | | | | | | | | | | |
|---|---|---|---|---|---|---|---|---|---|---|---|
| | condition | | | | | | | | | | |
| | Electrolyte | | | | | | | | | | |
| | Hydro- | | | | | | | | | Arithmetic | |
| | chloric | Nitric | | Acetic | | Current | Electrolytic | Quantity of | | average | |
| | acid | acid | Al iron | acid | Temperature | density | time | electricity | | roughness | |
| Support | (g/l) | (g/l) | (g/l) | (g/l) | (° C.) | (A/dm²) | (sec) | (c/dm²) | *1 | (Ra) (μm) | |
| 1 | | 11 | 8 | 10 | 30 | 25 | 7 | 175 | *2 | 0.53 | Inv. |
| 2 | | 11 | 8 | 10 | 30 | 25 | 7 | 175 | *3 | 0.52 | Inv. |
| 3 | 11 | | 8 | 10 | 30 | 30 | 10 | 300 | *2 | 0.48 | Inv. |
| 4 | 11 | | 8 | 10 | 30 | 30 | 10 | 300 | *3 | 0.47 | Inv. |
| 5 | | 11 | 8 | 10 | 30 | 25 | 7 | 175 | *2 | 0.54 | Comp. |
| 6 | | 11 | 8 | 10 | 30 | 25 | 7 | 175 | *3 | 0.53 | Comp. |
| 7 | 11 | | 8 | 10 | 30 | 30 | 10 | 300 | *2 | 0.49 | Comp. |
| 8 | 11 | | 8 | 10 | 30 | 30 | 10 | 300 | *3 | 0.48 | Comp. |
| 9 | | | | | | | | | | 0.50 | Comp. |
| 10 | | | | | | | | | | 0.49 | Comp. |
| 11 | | | | | | | | | | 0.48 | Comp. |
| 12 | | | | | | | | | | 0.47 | Comp. |
| 13 | | 11 | 8 | 10 | 30 | 25 | 7 | 175 | *2 | 0.53 | Comp. |
| 14 | | 11 | 8 | 10 | 30 | 25 | 7 | 175 | *3 | 0.52 | Comp. |
| 15 | | 11 | 8 | 10 | 30 | 25 | 7 | 175 | *2 | 0.53 | Comp. |
| 16 | | 11 | 8 | 10 | 30 | 25 | 7 | 175 | *3 | 0.52 | Comp. |
| 17 | | 11 | 8 | 10 | 30 | 25 | 7 | 175 | *2 | 0.53 | Comp. |
| 18 | | 11 | 8 | 10 | 30 | 25 | 7 | 175 | *3 | 0.52 | Comp. |
| 19 | | 11 | 8 | 10 | 30 | 25 | 7 | 175 | *2 | 0.53 | Comp. |
| 20 | | 11 | 8 | 10 | 30 | 25 | 7 | 175 | *3 | 0.52 | Comp. |

*1: Treatment after second electrolytically surface-roughening treatment
*2: Alkali etching treatment,
*3: Phosphoric acid-desmutting treatment
Inv.: Present invention,
Comp.: Comparative example

### {Preparation of Photopolymerization Type Planographic Printing Plate Material Samples 1-20 for FD-YAG Laser (532 nm) Light Source}

The photopolymerizable light sensitive layer coating solution having the following composition was coated on each of foregoing supports 1-20 with a wire bar, and dried at 95° C. for 1.5 minutes so as to give a light sensitive layer with a dry thickness of 1.6 g/m².

Then, the protective layer coating solution having the following composition was further coated on the resulting light sensitive layer with an applicator, and dried at 75° C. for 1.5 minutes to give a protective layer with a dry thickness of 1.7 g/m² to prepare photopolymerization type light sensitive planographic printing plate material samples each having a protective layer provided on a light sensitive layer.

### (Photopolymerizable Light Sensitive Layer Coating Solution)

| | | |
|---|---|---|
| Polymer binder B-1 (described below) | 40.0 | parts |
| Sensitizing dyes D1 (described below) and | 3.0 | parts |
| D2 (described below) (1:1 by weight) | | |
| Photopolymerization initiator | 4.0 | parts |
| (η-cumene-(η-cyclopentadienyl)iron | | |
| hexafluorophosphate) | | |
| Addition polymerizable ethylenically | 40.0 | parts |
| unsaturated monomer containing a double bond | | |
| M-3 (described previously) | | |
| Addition polymerizable ethylenically | 15.0 | parts |
| unsaturated monomer containing a double bond | | |
| NK ESTER G (polyethylene glycol dimethacrylate | | |
| produced by Shin-Nakamura Chemical Co., Ltd.) | | |
| Hindered amine compound (LS-770 produced | 0.1 | parts |
| by Sankyo Co., Ltd.) | | |
| Trihaloalkyl compound E-1 (described below) | 1.0 | parts |
| Phthalocyanine pigment (MHI #454 produced | 4.0 | parts |
| by Mikuni Color Ltd.) | | |
| Fluorine-containing surfactant (F-178K produced | 0.5 | parts |
| by Dainippon Ink Kagaku Kogyo Co., Ltd.) | | |
| Methyl ethyl ketone | 80 | parts |
| Cyclohexanone | 820 | parts |

### (Synthesis of Polymer Binder B-1)

One hundred and twenty-five parts (1.25 mol) of methyl methacrylate, 12 parts (0.1 mol) of ethyl methacrylate, 63 parts (0.73 mol) of methacrylic acid, 240 parts of cyclohexanone, 160 parts of isopropyl alcohol, and 5 parts of α,α′-azobisisobutyro-nitrile were charged in a three neck flask under nitrogen atmosphere, and reacted under nitrogen atmosphere for 6 hours at 80° C. in an oil bath to obtain a polymer. After that, 4 parts of triethylbenzylammonium chloride and 52 parts (0.73 mol) of glycidyl methacrylate were further added to the polymer, and reacted at 25° C. for 3 hours to obtain polymer binder B-1. The weight average molecular weight of the polymer binder was 55,000 (in terms of polystyrene), measured according to GPC.

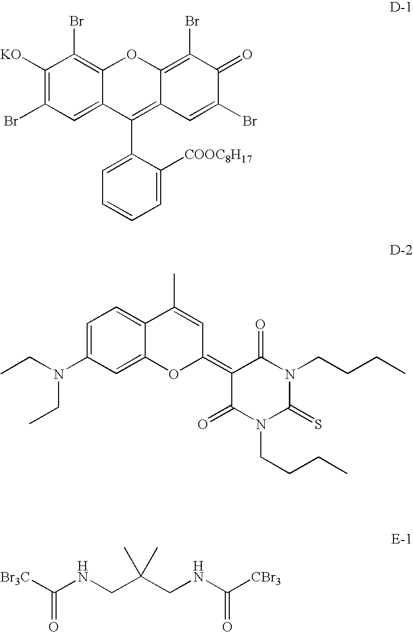

### (Protective Layer Coating Solution)

| | |
|---|---|
| Polyvinyl alcohol (GL-05, produced by Nippon Synthetic | 84 parts |
| Chemical Industry Co., Ltd.) | |
| Polyvinyl pyrrolidone (K-30, produced | 15 parts |
| by ISP Japan Co., Ltd.) | |
| Surfactant (Surfinol 465, produced by Nisshin Chemical | 0.5 parts |
| Industry Co., Ltd.) | |
| Water | 900 parts |

### (Image Formation)

Employing a CTP exposure device Tigercat (produced by ECRM Co., Ltd.) equipped with a FD-YAG laser light source, each of the photopolymerizable light sensitive planographic printing plate material samples obtained above was imagewise exposed at 150 μJ/cm² and at a resolution of 2400 dpi (“dpi” means the dot number per one inch, i.e., 2.54 cm) to obtain an image with a screen line number of 175. The image exposed to light includes a solid image and a dot image with a dot area of 1 to 99%. Subsequently, the exposed sample was subjected to a development treatment employing a CTP automatic developing machine (Raptor Polymer, produced by Glunz & Jensen Ltd.) fitted with a heating device, a pre-washing section to remove the protective layer before development, a development section charged the following developer composition, a washing section to remove the developer remaining on the developed sample after development, and a gumming solution to protect the surface of the developed sample (a solution obtained by diluting GW3, produced by Mitsubishi Chemical Co., Ltd., with water by a factor of 2). Thus, planographic printing plate samples 1-20 were obtained. Herein, the heating device was arranged so as to give a plate surface temperature of 105° C. for 15 seconds.

The plate insertion time taken from completion of exposure up to the heating device was within 30 seconds. Developer composition (Aqueous solution containing the following additives)

| | |
|---|---|
| Potassium silicate solution | 40.0 g/l |
| (containing 26% by weight of SiO₂ and | |
| 13.5% by weight of K₂O) | |
| Potassium hydroxide | 4.0 g/l |
| Ethylenediaminetetraacetic acid | 0.5 g/l |
| Sodiumsulfo-polyoxyethylene (13) naphthyl ether | 20.0 g/l |

Water was added to make a 1 liter developer. PH of the developer was 12.3.

### (Printing Method)

Employing the resulting printing plate samples, printing was carried out on a press (DAIYA1F-1 produced by Mitsubishi Jukogyo Co., Ltd.), wherein coated paper, printing ink (Soybean oil ink, “Naturalith 100” produced by Dainippon Ink Kagaku Co., Ltd.), and dampening water (SG-51, H solution produced by Tokyo Ink Co., Ltd., Concentration: 1.5%) were used. In this case, printing was carried out by thickening the paper base 0.1 mm thicker than in the case of standard setting, and by increasing printing pressure.

### (Dot Reproduction)

The exposure method described above was linearly corrected, and a dot image with a dot area of 1 to 99% was linearly reproduced on the printing plate. After the above-described printing was carried out for 1,000 copies, a dot area ratio of 50% output dot on the printed surface was measured, and an amount of dot gain from 50% dot was measured to be defined as a measure for dot reproduction. The less the amount of dot gain, the better the dot reproduction is. The results are shown in Table 4.

### (Anti-Stain Property)

The above-described printing was carried out for 10,000 copies, and subsequently, an ink form-roller was brought into contact with a printing plate to deposit ink onto the entire printing plate. The printing press was stopped in that situation, and left standing for one hour. The number of printing cycles in which stain at non-image portions can entirely be removed, after printing started, is evaluated as a measure of the anti-stain property. The less the number of printing cycles to remove stain at non-image portions, the better the anti-stain property is. The results are shown in Table 4.

### (Printing Durability)

The exposure was linearly corrected, and a dot image with a dot area of 1-99% was linearly reproduced on the resulting printing plate samples. Printing was carried out as above, and the number of prints printed until time when an image of a dot area of 5% was not reproduced was evaluated as a measure of printing durability. The more the number is, the higher the printing durability. The results are shown in Table 4.

TABLE 4

| | | | Anti-stain | | |
|---|---|---|---|---|---|
| | | | property | | |
| | | | The number of | | |
| | | Dot | copies | Printing | |
| Plano- | | reproduction | consumed by | durability | |
| graphic | | Amount of | the time | The | |
| printing | | dot gain | stain | number of | |
| plate | Support | % | disappears | copies | |
| 1 | 1 | 12 | 12 | 280000 | Inv. |
| 2 | 2 | 14 | 13 | 300000 | Inv. |
| 3 | 3 | 15 | 14 | 250000 | Comp. |
| 4 | 4 | 17 | 15 | 280000 | Comp. |
| 5 | 5 | 20 | 20 | 230000 | Comp. |
| 6 | 6 | 22 | 23 | 240000 | Comp. |
| 7 | 7 | 25 | 22 | 230000 | Comp. |
| 8 | 8 | 27 | 25 | 240000 | Comp. |
| 9 | 9 | 20 | 20 | 200000 | Comp. |
| 10 | 10 | 22 | 23 | 210000 | Comp. |
| 11 | 11 | 25 | 25 | 230000 | Comp. |
| 12 | 12 | 27 | 27 | 240000 | Comp. |
| 13 | 13 | 20 | 20 | 180000 | Comp. |
| 14 | 14 | 22 | 23 | 190000 | Comp. |
| 15 | 15 | 25 | 24 | 220000 | Comp. |
| 16 | 16 | 27 | 26 | 230000 | Comp. |
| 17 | 17 | 20 | 22 | 220000 | Comp. |
| 18 | 18 | 22 | 24 | 230000 | Comp. |
| 19 | 19 | 25 | 22 | 220000 | Comp. |
| 20 | 20 | 27 | 24 | 230000 | Comp. |

Inv.: Present invention
Comp.: Comparative example

As is clear from Table 4, it is to be understood that planographic printing plate material samples of the present invention exhibit excellent dot reproduction, printing durability and anti-stain property during printing at high printing pressure.

### Example 2

### (Preparation of Photopolymerization Type Planographic Printing Plate Material Samples 21-40 for Violet Light Source)

The photopolymerizable light sensitive layer coating solution having the following composition was coated on each of supports 1-20 with a wire bar, and dried at 95° C. for 1.5 minutes so as to give a light sensitive layer with a dry thickness of 1.9 g/m².

Subsequently, the protective layer coating solution having the foregoing composition was coated on the resulting light sensitive layer with an applicator, and dried at 75° C. for 1.5 minutes to give a protective layer with a dry thickness of 1.7 g/m² to prepare photopolymerizable light sensitive planographic printing plate material samples each having a protective layer provided on a light sensitive layer.

### (Photopolymerizable Light Sensitive Layer Coating Solution)

| | | |
|---|---|---|
| Polymer binder B-1 (described previously) | 40.0 | parts |
| Photopolymerization initiator (η-Cumene-(η- | 3.0 | parts |
| cyclopentadienyl)iron hexafluorophosphate) | | |
| Sensitizing dyes D3 and D4 (1:1 by weight) | 4.0 | parts |
| Addition polymerizable ethylenically | 40.0 | parts |
| unsaturated monomer containing | | |
| a double bond M-3 (described previously) | | |
| Addition polymerizable ethylenically | 7.0 | parts |
| unsaturated monomer containing a double bond | | |
| NK ESTER G (polyethylene glycol dimethacrylate | | |
| produced by Shin-Nakamura Chemical Co., Ltd.) | | |
| Cationically polymerizable group-containing | 8.0 | parts |
| compound C-1 (described below) | | |
| Hindered amine compound | 0.1 | parts |
| (LS-770 produced by Sankyo Co., Ltd.) | | |
| Trihaloalkyl compound E-1 (described previously) | 5.0 | parts |
| Phthalocyanine pigment (MHI #454 produced | 7.0 | parts |
| by Mikuni Color Ltd.) | | |
| Fluorine-containing surfactant (F-178K produced | 0.5 | parts |
| by Dainippon Ink Kagaku Kogyo Co., Ltd.) | | |
| Methyl ethyl ketone | 80 | parts |
| Cyclohexanone | 820 | parts |
| Cyclohexanone | 820 | parts |

D-3

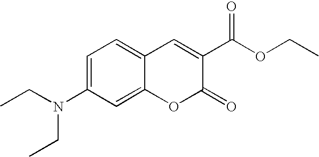

D-4

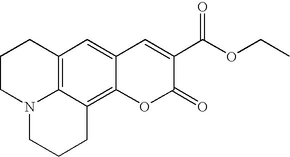

C-1

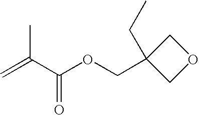

### (Image Formation)

Employing a plate setter (modified Tigercat ECRM) fitted with a 408 nm laser having an output power of 30 mW, each of the photopolymerizable light sensitive planographic printing plate material samples obtained above was imagewise exposed at 50 μJ/cm² and at a resolution of 2400 dpi (“dpi” means the dot number per 1 inch, i.e., 2.54 cm) to obtain an image with a screen line number of 175. The image exposed to light includes a solid image and a dot image with a dot area of 1 to 99%. Subsequently, the exposed sample was subjected to a development treatment employing a CTP automatic developing machine (Raptor Polymer, produced by Glunz & Jensen Ltd.) fitted with a heating device, a pre-washing section to remove the protective layer before development, a development section charged the following developer composition, a washing section to remove the developer remaining on the developed sample after development, and a gumming solution to protect the surface of the developed sample (a solution obtained by diluting GW-3, produced by Mitsubishi Chemical Co., Ltd., with water by a factor of 2). Thus, planographic printing plate samples 21-40 were obtained. Herein, the heating device was arranged so as to give a plate surface temperature of 105° C. for 15 seconds. The plate insertion time taken from completion of exposure up to the heating device was within 30 seconds.

(Printing Method, Dot reproduction, Printing Durability and Anti-Stain Property)

The evaluation was made by the same method as described before. The results are shown in Table. 5.

TABLE 5

| | | | Anti-stain | | |
|---|---|---|---|---|---|
| | | | property | | |
| | | | The number of | | |
| | | Dot | copies | Printing | |
| Plano- | | reproduction | consumed by | durability | |
| graphic | | Amount of | the time | The | |
| printing | | dot gain | stain | number of | |
| plate | Support | % | disappears | copies | |
| 21 | 1 | 12 | 12 | 250000 | Inv. |
| 22 | 2 | 14 | 13 | 270000 | Inv. |
| 23 | 3 | 15 | 14 | 220000 | Comp. |
| 24 | 4 | 17 | 15 | 250000 | Comp. |
| 25 | 5 | 20 | 20 | 200000 | Comp. |
| 26 | 6 | 22 | 23 | 210000 | Comp. |
| 27 | 7 | 25 | 22 | 200000 | Comp. |
| 28 | 8 | 27 | 25 | 210000 | Comp. |
| 29 | 9 | 20 | 20 | 170000 | Comp. |
| 30 | 10 | 22 | 23 | 180000 | Comp. |
| 31 | 11 | 25 | 25 | 200000 | Comp. |
| 32 | 12 | 27 | 27 | 210000 | Comp. |
| 33 | 13 | 20 | 20 | 150000 | Comp. |
| 34 | 14 | 22 | 23 | 160000 | Comp. |
| 35 | 15 | 25 | 24 | 190000 | Comp. |
| 36 | 16 | 27 | 26 | 200000 | Comp. |
| 37 | 17 | 20 | 22 | 190000 | Comp. |
| 38 | 18 | 22 | 24 | 200000 | Comp. |
| 39 | 19 | 25 | 22 | 190000 | Comp. |
| 40 | 20 | 27 | 24 | 200000 | Comp. |

Inv.: Present invention
Comp.: Comparative example

As is clear from Table 5, it is to be understood that planographic printing plate material samples of the present invention exhibit excellent dot reproduction, printing durability and anti-stain property during printing at high printing pressure

### Example 3

### {Preparation of Photopolymerization Type Planographic Printing Plate Material Samples 41-60 for Infrared Laser (830 nm) Light Source}

The light sensitive layer coating solution having the following composition was coated on each of supports 1-20 with a wire bar, and dried at 95° C. for 1.5 minutes so as to give a light sensitive layer with a dry thickness of 1.5 g/m².

Subsequently, the protective layer coating solution having the foregoing composition was coated on the resulting light sensitive layer with an applicator, and dried at 75° C. for 1.5 minutes to give a protective layer with a dry thickness of 1.7 g/m² to prepare photopolymerizable light sensitive planographic printing plate material samples each having a protective layer provided on a light sensitive layer.

### (Light Sensitive Layer Coating Solution)

| | | |
|---|---|---|
| Polymer binder B-1 (described previously) | 40.0 | parts |
| Infrared absorbing dye D-5 (described below) | 2.5 | parts |
| N-Phenylglycine benzyl ester | 4.0 | parts |
| Addition polymerizable ethylenically | 40.0 | parts |
| unsaturated monomer containing a double bond | | |
| M-3 (described previously) | | |
| Addition polymerizable ethylenically | 7.0 | parts |
| unsaturated monomer containing a double bond | | |
| NK ESTER G (polyethylene glycol dimethacrylate | | |
| produced by Shin-Nakamura Chemical Co., Ltd.) | | |
| Cationically polymerizable group-containing | 8.0 | parts |
| compound C-1 (described previously) | | |
| Hindered amine compound (LS-770 produced by | 0.1 | parts |
| Sankyo Co., Ltd.) | | |
| Trihaloalkyl compound E-1 (described previously) | 5.0 | parts |
| Phthalocyanine pigment (MHI #454 | 7.0 | parts |
| produced by Mikuni Sikisosha) | | |
| Fluorine-containing surfactant (F-178K produced | 0.5 | parts |
| by Dainippon Ink Kagaku Kogyo Co., Ltd.) | | |
| Methyl ethyl ketone | 80 | parts |
| Cyclohexanone | 820 | parts |

D-5

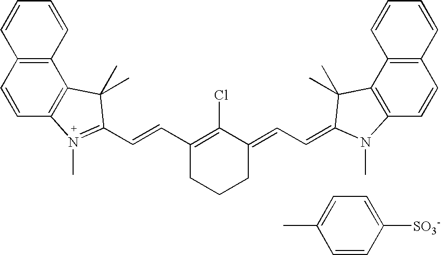

### (Image Formation)

Employing a plate setter (Trend Setter 3244 produced by Creo Co., Ltd.) fitted with a 830 nm light source, each of the light sensitive planographic printing plate material samples obtained above was imagewise exposed at 150 mJ/cm² and at a resolution of 2400 dpi (“dpi” means the dot number per 1 inch, i.e., 2.54 cm) to obtain an image with a screen line number of 175.

The image exposed to light includes a solid image and a dot image with a dot area of 1 to 99%. Subsequently, the exposed sample was subjected to a development treatment employing a CTP automatic developing machine (PHW 23-V, produced by Technigraph Co., Ltd.) fitted with a heating device, a pre-washing section to remove the protective layer before development, a development section charged the following developer composition, a washing section to remove the developer remaining on the developed sample after development, and a gumming solution to protect the surface of the developed sample (a solution obtained by diluting GW-3, produced by Mitsubishi Chemical Co., Ltd., with water by a factor of 2). Thus, planographic printing plate samples 41-60 were obtained. Herein, the heating device was arranged so as to give a plate surface temperature of 115° C. for 15 seconds. The plate insertion time taken from completion of exposure up to the heating device was within 30 seconds.

### (Printing Method, Dot Reproduction, Printing Durability and Anti-Stain Property)

The evaluation was made by the same method as described before. The results are shown in Table 6.

TABLE 6

| | | | Anti-stain | | |
|---|---|---|---|---|---|
| | | | property | | |
| | | | The number of | | |
| | | Dot | copies | Printing | |
| Plano- | | reproduction | consumed by | durability | |
| graphic | | Amount of | the time | The | |
| printing | | dot gain | stain | number of | |
| plate | Support | % | disappears | copies | |
| 41 | 1 | 12 | 12 | 220000 | Inv. |
| 42 | 2 | 14 | 13 | 240000 | Inv. |
| 43 | 3 | 15 | 14 | 190000 | Comp. |
| 44 | 4 | 17 | 15 | 220000 | Comp. |
| 45 | 5 | 20 | 20 | 170000 | Comp. |
| 46 | 6 | 22 | 23 | 180000 | Comp. |
| 47 | 7 | 25 | 22 | 170000 | Comp. |
| 48 | 8 | 27 | 25 | 180000 | Comp. |
| 49 | 9 | 20 | 20 | 140000 | Comp. |
| 50 | 10 | 22 | 23 | 150000 | Comp. |
| 51 | 11 | 25 | 25 | 170000 | Comp. |
| 52 | 12 | 27 | 27 | 180000 | Comp. |
| 53 | 13 | 20 | 20 | 120000 | Comp. |
| 54 | 14 | 22 | 23 | 130000 | Comp. |
| 55 | 15 | 25 | 24 | 160000 | Comp. |
| 56 | 16 | 27 | 26 | 170000 | Comp. |
| 57 | 17 | 20 | 22 | 160000 | Comp. |
| 58 | 18 | 22 | 24 | 170000 | Comp. |
| 59 | 19 | 25 | 22 | 160000 | Comp. |
| 60 | 20 | 27 | 24 | 170000 | Comp. |

Inv.: Present invention
Comp.: Comparative example

As is clear from Table 6, it is to be understood that planographic printing plate material samples of the present invention exhibit excellent dot reproduction, printing durability and anti-stain property during printing at high printing pressure.

### Example 4

### {Preparation of Positive Working Planographic Printing Plate Material Samples 61-80 for Infrared Laser (830 nm) Light Source}

The light sensitive layer coating solution having the following composition was coated on each of supports 1-20 with a wire bar, and dried at 95° C. for 1.5 minutes so as to give a light sensitive layer with a dry thickness of 1.5 g/m² to prepare light sensitive planographic printing plate material samples.

### (Light Sensitive Layer Coating Solution)

| | | |
|---|---|---|
| Novolak resin (m-cresol/p-cresol = 60/40, | 1.0 | part |
| a weight average molecular weight of 7,000, | | |
| and an unreacted cresol content of | | |
| 0.5% by weight) | | |
| Infrared absorbing dye D-5 (described previously) | 0.1 | parts |
| Tetrahydrophthalic anhydride | 0.05 | parts |
| p-toluene sulfonic acid | 0.002 | parts |
| Product in which a 6-hydroxy-β-naphthalene | 0.02 | parts |
| sulfonic acid is formed from | | |
| a counter ion of ethyl violet | | |
| Fluorine-containing surfactant (F-178K produced | 0.5 | parts |
| by Dainippon Ink Kagaku Kogyo Co., Ltd,) | | |
| Methyl ethyl ketone | 12 | parts |

### (Image Formation)

Employing a plate setter (Trend Setter 3244 produced by Creo Co., Ltd.) fitted with a 830 nm light source, each of the light sensitive planographic printing plate material samples obtained above was imagewise exposed at 150 mJ/cm² and at a resolution of 2400 dpi (“dpi” means the dot number per 1 inch, i.e., 2.54 cm) to obtain an image with a screen line number of 175. The image exposed to light includes a solid image and a dot image with a dot area of 1 to 99%. Subsequently, the exposed sample was subjected to a development treatment employing a CTP automatic developing machine (Raptor Polymer, produced by Glunz & Jensen Ltd.) fitted with a heating device, a pre-washing section to remove the protective layer before development, a development section charged the following developer composition, a washing section to remove the developer remaining on the developed sample after development, and a gumming solution to protect the surface of the developed sample (a solution obtained by diluting GW-3r produced by Mitsubishi Chemical Co., Ltd., with water by a factor of 2). Thus, planographic printing plate samples 61-80 were obtained. Herein, the heating device was switched off, and water was not supplied to the pre-washing section for removing a protective layer before development. The plate insertion time taken from completion of exposure up to the heating device was also within 30 seconds.

### Developer Composition (Aqueous Solution Containing the Following Additives)

| | |
|---|---|
| Potassium salt formed from D-sorbitol and | 50.0 g/l |
| potassium oxide K₂O (a combination of | |
| non-reducing sugar and a base) | |
| Deforming agent Orfin AK-02 (produced by | 0.15 g/l |
| Nisshin Chemical Industry Co., Ltd.) | |
| C₁₂H₂₅W (CH₂CH₂COONa)₂ | 1.0 g/l |

Water was added to make 1 liter.

### (Printing Method, Dot Reproduction, Printing Durability and Anti-Stain Property)

The evaluation was made by the same method as described before. The results are shown in Table 7.

TABLE 7

| | | | Anti-stain | | |
|---|---|---|---|---|---|
| | | | property | | |
| | | | The number of | | |
| | | Dot | copies | Printing | |
| Plano- | | reproduction | consumed by | durability | |
| graphic | | Amount of | the time | The | |
| printing | | dot gain | stain | number of | |
| plate | Support | % | disappears | copies | |
| 61 | 1 | 14 | 17 | 190000 | Inv. |
| 62 | 2 | 16 | 18 | 210000 | Inv. |
| 63 | 3 | 17 | 19 | 160000 | Comp. |
| 64 | 4 | 19 | 20 | 190000 | Comp. |
| 65 | 5 | 22 | 25 | 140000 | Comp. |
| 66 | 6 | 24 | 28 | 150000 | Comp. |
| 67 | 7 | 27 | 27 | 140000 | Comp. |
| 68 | 8 | 29 | 30 | 150000 | Comp. |
| 69 | 9 | 22 | 25 | 110000 | Comp. |
| 70 | 10 | 24 | 28 | 120000 | Comp. |
| 71 | 11 | 27 | 30 | 140000 | Comp. |
| 72 | 12 | 29 | 32 | 150000 | Comp. |
| 73 | 13 | 22 | 25 | 90000 | Comp. |
| 74 | 14 | 24 | 28 | 100000 | Comp. |
| 75 | 15 | 27 | 29 | 130000 | Comp. |
| 76 | 16 | 29 | 31 | 140000 | Comp. |
| 77 | 17 | 22 | 27 | 130000 | Comp. |
| 78 | 18 | 24 | 29 | 140000 | Comp. |
| 79 | 19 | 27 | 27 | 130000 | Comp. |
| 80 | 20 | 29 | 29 | 140000 | Comp. |

Inv.: Present invention
Comp.: Comparative example

As is clear from Table 7, it is to be understood that planographic printing plate material samples of the present invention exhibit excellent dot reproduction, printing durability and anti-stain property during printing at high printing pressure.

### Example 5

### {Preparation of On-Press Development Type Planographic Printing Plate Material Samples 81-100 for Infrared Laser (830 nm) Light Source}

### (Preparation of Hydrophilic Layer)

The material with the following composition was mixed while sufficiently stirring employing a homogenizer, and filtered to obtain a hydrophilic layer coating solution having a solid content of 15% by weight.

The resulting hydrophilic layer coating solution was coated on each of supports 1-20 with a wire bar, dried at 100° C. for 3 minutes so as to give a hydrophilic layer with a dry thickness of 2.0 g/m², and subsequently an aging treatment was conducted at 60° C. for 24 hours.

### (Hydrophilic Layer)

| | | |
|---|---|---|
| Metal oxide particles having a light-to-heat | 12.50 | parts |
| conversion function, Black iron oxide particles | | |
| ABL-207 (produced by Titan Kogyo K.K., | | |
| octahedral form, average particle diameter: | | |
| 0.2 μm, specific surface area: 6.7 m²/g, | | |
| Hc: 9.95 kA/m, σs: 85.7 Am²/kg, σr/σs: 0.112) | | |
| Colloidal silica (alkali based) Snowtex XS | 60.62 | parts |
| (produced by Nissan Kagaku Co., Ltd.; | | |
| solid content: 20% by weight) | | |
| Aqueous 10% by weight trisodium | 1.13 | parts |
| phosphate•dodecahydrate solution | | |
| (Reagent produced by Kanto Kagaku Co., Ltd.) | | |
| Aqueous 10% by weight solution of | 2.50 | parts |
| water-soluble chitosan Flownack S | | |
| (produced by Kyowa Technos Co., Ltd.) | | |
| Aqueous 1% by weight solution of surfactant | 1.25 | parts |
| Surfinol 465 (produced by Air Products Co., Ltd.) | | |
| Pure water | 22.00 | parts |

Subsequently, the following image formation layer coating solution was coated employing a wire bar, dried and then, an aging treatment was conducted to obtain printing plate material samples.

### Image Formation Layer:

Dry thickness; 1.50 g/m²,
Drying condition; 55° C. for 3 minutes, and
Aging condition; 40° C. for 24 hours

### (Image Formation Layer Coating Solution)

| | |
|---|---|
| Aqueous polyurethane Takelac W-615 (a solid | 17.1 parts |
| content of 35% by weight, produced | |
| by Mitsui Takeda Chemical Co., Ltd.) | |
| Aqueous block isocyanate Takenate XWB-72-N67 | 7.1 parts |
| (a solid content of 45% by weight, | |
| produced by Mitsui Takeda Chemical Co., Ltd.) | |
| Aqueous solution (a solid content of 10% by weight) | 5.0 parts |
| of sodium acrylate Aqualic DL522 | |
| (produced by Nippon Shokubai Co., Ltd.) | |
| Ethanol solution (a solid content of 1% by weight) | 30.0 parts |
| of light-to-heat conversion dye ADS 830AT | |
| (produced by American Dye Source Co., Ltd.) | |
| Pure water | 40.8 parts |

### (Image Formation)

Employing a plate setter (Trend Setter 3244, produced by Creo Co., Ltd.), fitted with a 830 nm laser light source, the planographic printing plate material sample obtained above was imagewise exposed at 220 mJ/cm² and at a resolution of 2400 dpi (“dp” means the dot number per one inch, i.e., 2.54 cm) to obtain an image with a screen line number of 175. Thus, planographic printing plate samples 61-75 were obtained. The image exposed to light includes a solid image and a dot image with a dot area of 1 to 99%.

### (Printing Method)

Each of the resulting planographic printing plate samples was mounted on the plate cylinder of a press (DAIYA1F-1 produced by Mitsubishi Heavy industries, Ltd.), and printing was carried out wherein a coat paper, printing ink (soybean oil-based ink “Naturalist 100” produced by Dainippon Ink Kagaku Kogyo Co., Ltd.) and dampening water (SG-51, H solution produced by Tokyo Ink Co., Ltd., a concentration of 1.5%) were used. In this case, printing was carried out by thickening the paper base 0.1 mm thicker than in the case of standard setting, and by increasing printing pressure.

### (Dot Reproduction, Printing Durability and Anti-Stain Property)

The evaluation was made by the same method as described before. The results are shown in Table 8.

TABLE 8

| | | | Anti-stain | | |
|---|---|---|---|---|---|
| | | | property | | |
| | | | The number of | | |
| | | Dot | copies | Printing | |
| Plano- | | reproduction | consumed by | durability | |
| graphic | | Amount of | the time | The | |
| printing | | dot gain | stain | number of | |
| plate | Support | % | disappears | copies | |
| 81 | 1 | 19 | 22 | 110000 | Inv. |
| 82 | 2 | 21 | 23 | 130000 | Inv. |
| 83 | 3 | 22 | 24 | 80000 | Comp. |
| 84 | 4 | 24 | 25 | 110000 | Comp. |
| 85 | 5 | 27 | 30 | 60000 | Comp. |
| 86 | 6 | 29 | 33 | 70000 | Comp. |
| 87 | 7 | 32 | 32 | 60000 | Comp. |
| 88 | 8 | 34 | 35 | 70000 | Comp. |
| 89 | 9 | 27 | 30 | 30000 | Comp. |
| 90 | 10 | 29 | 33 | 40000 | Comp. |
| 91 | 11 | 32 | 35 | 60000 | Comp. |
| 92 | 12 | 34 | 37 | 70000 | Comp. |
| 93 | 13 | 27 | 30 | 10000 | Comp. |
| 94 | 14 | 29 | 33 | 20000 | Comp. |
| 95 | 15 | 32 | 34 | 50000 | Comp. |
| 96 | 16 | 34 | 36 | 60000 | Comp. |
| 97 | 17 | 27 | 32 | 50000 | Comp. |
| 98 | 18 | 29 | 34 | 60000 | Comp. |
| 99 | 19 | 32 | 32 | 50000 | Comp. |
| 100 | 20 | 34 | 34 | 60000 | Comp. |

Inv.: Present invention
Comp.: Comparative example

As is clear from Table 8, it is to be understood that planographic printing plate material samples of the present invention exhibit excellent dot reproduction, printing durability and anti-stain property during printing at high printing pressure.

1. A method of manufacturing a support for a planographic printing plate material, comprising the steps of:
(1) conducting an alkali etching treatment on an aluminum plate as the support;
(2) electrochemically conducting a surface-roughening treatment in a nitric acid solution as well as in a hydrochloric acid solution in arbitrary order; and
(3) conducting an anodizing treatment, in this order,
wherein the aluminum plate comprises a Mg content of 0.1-0.4% by weight, a Ga content of 0.001-0.02% by weight, and an Al content of at least 99.0% by weight.

2. The method of claim 1, comprising the steps of:
(1) conducting an alkali etching treatment on an aluminum plate as the support;
(2) electrochemically conducting a surface-roughening treatment in a nitric acid solution;
(3) electrochemically conducting a surface-roughening treatment in a hydrochloric acid solution; and
(4) conducting an anodizing treatment, in this order.

3. A method of manufacturing a support for a planographic printing plate material, comprising the steps of:
(1) conducting an alkali etching treatment on an aluminum plate as the support;
(2) electrochemically conducting a surface-roughening treatment in a nitric acid solution;
(3) conducting the alkali etching treatment;
(4) electrochemically conducting a surface-roughening treatment in a hydrochloric acid solution;
(5) conducting the alkali etching treatment; and
(6) conducting an anodizing treatment, in this order,
wherein the aluminum plate comprises a Mg content of 0.1-0.4% by weight, a Ga content of 0.001-0.02% by weight, and an Al content of at least 99.0% by weight.

4. A method of manufacturing a support for a planographic printing plate material, comprising the steps of:
(1) conducting an alkali etching treatment on an aluminum plate as the support;
(2) electrochemically conducting a surface-roughening treatment in a nitric acid solution;
(3) conducting a phosphoric acid-desmutting treatment;
(4) electrochemically conducting a surface-roughening treatment in a hydrochloric acid solution;
(5) conducting the phosphoric acid-desmutting treatment; and
(6) conducting an anodizing treatment, in this order,
wherein the aluminum plate comprises a Mg content of 0.1-0.4% by weight, a Ga content of 0.001-0.02% by weight, and an Al content of at least 99.0% by weight.

5. The support manufactured by the method of claim 1.

6. A planographic printing plate material comprising the support of claim 5 and provided thereon, an image formation layer.

7. The planographic printing plate material of claim 6,
wherein the image formation layer is a thermosensitive image formation layer.

8. The planographic printing plate material of claim 6,
wherein the image formation layer is a photopolymerizable image formation layer.

9. The planographic printing plate material of claim 6,
wherein the image formation layer is an on-press developable layer.
